(19) United States
(12) Patent Application Publication
(10) Pub. No.: US 2014/0120681 A1
(43) Pub. Date: May 1, 2014

(54) METHODS OF FABRICATING SEMICONDUCTOR DEVICES HAVING GATE STRUCTURE

(71) Applicant: SAMSUNG ELECTRONICS CO., LTD., Suwon-si (KR)

(72) Inventors: Chong-Kwang CHANG, Bucheon-si (KR); Se-Young LEE, Suwon-si (KR); Seung-Ho CHAE, Hwaseong-si (KR)

(21) Appl. No.: 13/922,571

(22) Filed: Jun. 20, 2013

(30) Foreign Application Priority Data
Oct. 25, 2012 (KR) 10-2012-0119313

(51) Int. Cl. H01L 29/66

(52) U.S. Cl. CPC H01L 29/66477
USPC 438/301; 438/513; 438/585

(57) ABSTRACT

A method of fabricating a semiconductor device includes forming a gate electrode structure on a substrate, forming a first spacer material layer covering the gate electrode structure, forming a second spacer material layer covering the first spacer material layer, and etching the first and second spacer material layers using an etch-back process to form first and second spacers.

### CROSS-REFERENCE TO RELATED APPLICATION

This application claims priority under 35 U.S.C. §119 to Korean Patent Application No. 10-2012-0119313 filed on Oct. 25, 2012, the disclosure of which is hereby incorporated by reference in its entirety.

### BACKGROUND

1. Field

Some example embodiments relate to a semiconductor device having a gate structure and methods of fabricating the same.

2. Description of Related Art

As the degree of integration of a semiconductor device is increased, forming a gate structure having desirable performance becomes difficult. For example, during deposition and etching processes performed to form a gate structure, influence given by accumulated charges is significant.

### SUMMARY

Some example embodiments provide a semiconductor device having a gate structure.

Other example embodiments provide a method of fabricating a semiconductor device having a gate structure.

The inventive concepts should not be limited by the above description, and other unmentioned aspects will be clearly understood by one of ordinary skill in the art from embodiments described herein.

In accordance with an example embodiment, a method of fabricating a semiconductor device includes forming a gate electrode structure on a substrate, forming a first spacer material layer covering the gate electrode structure, forming a second spacer material layer covering the first spacer material layer, and etching the first and second spacer material layers using an etch-back process to form first and second spacers.

In accordance with another example embodiment, a method of fabricating a semiconductor device includes forming a gate electrode structure on a substrate, forming a gate structure on the gate electrode structure including forming a spacer material layer covering the gate electrode structure, and etching the spacer material layer using an etch-back process to form a spacer on a side of the gate electrode structure, the etch-back process including continually performing a first etching process using a gas containing a first fluorine (F) content, a second etching process using a gas containing a second F content lower than the first F content, and a plasma discharge process using a gas containing N₂, implanting impurity ions into the substrate using the gate structure as an ion implantation mask to form a source/drain region, forming an interlayer insulating layer covering the gate structure and the source/drain region, and forming a contact structure vertically penetrating the interlayer insulating layer to be in contact with one of the source/drain region.

In accordance with another example embodiment, a method of fabricating a semiconductor device includes forming a gate electrode structure on a substrate, forming at least one spacer material layer covering at least a portion of the gate electrode structure, and etching the at least one spacer material layer using an etch-back process including continually performing a first etching process having a first etch selectivity, a second etching process having a second etch selectivity less than the first etch selectivity and a plasma ion implantation process.

Details of the other example embodiments may be included in the detailed description and the drawings.

### BRIEF DESCRIPTION OF THE DRAWINGS

The foregoing and other features and advantages of the inventive concepts will be apparent from the more particular description of example embodiments, as illustrated in the accompanying drawings in which like reference characters refer to the same parts throughout the different views. The drawings are not necessarily to scale, emphasis instead being placed upon illustrating the principles of the inventive concepts. In the drawings:

FIGS. 1 to 3 are longitudinal cross-sectional views of semiconductor devices according to various example embodiments;

FIGS. 4A to 4M, 5A to 5M, 6A to 6Q are cross-sectional views illustrating methods of fabricating a semiconductor device according to various example embodiments;

FIG. 7A conceptually illustrates a semiconductor module including at least one of semiconductor devices according to an example embodiment;

FIG. 7B is a conceptual block diagram of an electronic system including at least one of semiconductor devices according to another example embodiment;

FIG. 7C is a block diagram of another electronic system including at least one of semiconductor devices according to another example embodiment; and

FIG. 7D is a schematic block diagram of a mobile device including at least one of semiconductor devices according to another example embodiment.

### DETAILED DESCRIPTION OF EMBODIMENTS

Advantages, features and a method of achieving them will now be described more fully with reference to the accompanying drawings in which some example embodiments are shown. This inventive concepts may, however, be embodied in different forms and should not be construed as limited to the embodiments set forth herein. Rather, these embodiments are provided so that this disclosure is thorough and complete and fully conveys the scope of the inventive concepts to those skilled in the art.

The terminology used herein is for the purpose of describing particular embodiments only and is not intended to be limiting of the present inventive concepts. As used herein, the singular forms “a,” “an” and “the” are intended to include the plural forms as well, unless the context clearly indicates otherwise. It will be further understood that the terms “comprises,” “includes,” “including” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented and the spatially relative descriptors used herein interpreted accordingly.

Also, the inventive concepts may be described with reference to schematic cross-sectional views or plan views, which are schematic diagrams of example embodiments. As such, variations from the shapes of the illustrations, as a result, for example, of manufacturing techniques and/or tolerances, are to be expected. For example, an etched region illustrated in a right angle may be rounded have a given (or, alternatively predetermined) curvature. Thus, example embodiments should not be construed as being limited to the particular shapes of regions illustrated herein, but are to include deviations in shapes that result from, e.g., a manufacturing process. Thus, the regions illustrated in the drawings are schematic in nature and are not intended to limit the scope of the inventive concepts.

Like reference numerals designate like elements throughout the specification. Therefore, even though identical or similar reference numerals are not described in the corresponding drawing, they may be described with reference to the other drawings. Also, even though no reference numeral is indicated, it may be described with reference to the other drawings.

FIGS. 1 to 3 are longitudinal cross-sectional views of semiconductor devices 10a to 10c according to various example embodiments. Referring to FIG. 1, a semiconductor device 10a according to an example embodiment includes a gate structure 20 formed on a substrate 11, and source/drain regions 50 formed in the substrate 11.

The substrate 11 may include single crystalline silicon. For example, the substrate 11 may include a bulk silicon wafer or a silicon-on-insulator (SOI) wafer.

The gate structure 20 may include a gate insulating layer 22 directly formed on the substrate 11, a gate electrode 30 formed on the gate insulating layer 22, an inner gate spacer 41 formed on sides of the gate insulating layer 22 and the gate electrode 30, and an outer gate spacer 42 formed on a side and surface of the inner gate spacer 41. The gate structure 20 may further include a hard mask pattern 13 formed on the gate electrode 30.

The gate insulating layer 22 may include oxidized silicon or silicon oxide. For example, the gate insulating layer 22 may be formed by oxidizing a surface of the substrate 11. Alternatively, the gate insulating layer 22 may be formed by depositing silicon oxide on the surface of the substrate 11.

A side of the gate electrode 30 may be vertically aligned with a side of the gate insulating layer 22. The gate electrode 30 may include a conductive material such as doped polysilicon, a metal, metal silicide, and a metal compound.

The inner gate spacer 41 may be formed on the side of the gate electrode 30, the side of the gate insulating layer 22, and a part of the surface of the substrate 11. The inner gate spacer 41 may include silicon oxide formed using a deposition process such as a plasma enhanced chemical vapor deposition (PE-CVD) process. The PE-CVD process may include generating plasma in a reaction chamber.

The outer gate spacer 42 may be formed on the side and top surface of the inner gate spacer 41. An outer end portion of the outer gate spacer 42 may be vertically aligned with an outer end portion of the inner gate spacer 41. A top end portion of the outer gate spacer 42 may be horizontally aligned with a top end portion of the inner gate spacer 41. The outer gate spacer 42 may be formed by performing an atomic layer deposition (ALD) or molecular layer deposition (MLD) process using a remote plasma process. The outer gate spacer 42 may include silicon nitride (SiN). The remote plasma process may include generating plasma at the outside of the reaction chamber to be injected into the chamber. In addition, the outer gate spacer 42 may be formed using etching and discharge processes. For example, the outer gate spacer 42 may be formed by continually performing a first etching process having a relatively high etch selectivity, a second etching process having a relatively low etch selectivity, and a plasma discharge process including a relatively large amount of ions and electrons.

The hard mask pattern 13 may be formed on the gate electrode 30 so that a side of the hard mask pattern 13 is aligned with the side of the gate electrode 30. A lower portion of a side of the hard mask pattern 13 may be covered to be in contact with the inner gate spacer 41. An upper portion of the hard mask pattern 13 may not be covered with the inner gate spacer 41. In another example embodiment, the hard mask pattern 13 may be omitted.

The source/drain regions 50 may include a lower source/drain region 51, an upper source/drain region 52 formed on the lower source/drain region 51 to have an ascending surface, and a silicide region 53. The source/drain regions 50 may include impurity atoms such as phosphorus (P), arsenic (As), or boron (B). The silicide region 53 may be formed in the upper source/drain regions 52. A lateral end portion of the lower source/drain regions 51 may be approximately aligned with an outer end portion of the outer gate spacer 42. The upper source/drain regions 52 may be disposed at a higher level than a boundary between the substrate 11 and the gate insulating layer 22. For example, the upper source/drain regions 52 may include a single crystalline silicon region grown using an epitaxial growth process. The upper source/drain regions 52 may be in contact with the inner gate spacer 41 and the outer gate spacer 42. The silicide region 53 may include nickel silicide, cobalt silicide, tungsten silicide, titanium silicide, or other metallic silicide.

The semiconductor device 10a may further include an interlayer insulating layer 70 covering a gate structure 20 and the source/drain regions 50, and a contact structure 60 vertically penetrating the interlayer insulating layer 70 to be in contact with the source drain regions 50.

The interlayer insulating layer 70 may include silicon oxide formed using a deposition process. For example, the interlayer insulating layer 70 may include silicon oxide formed using a source gas such as tetra ethyl ortho silicate (TEOS) and plasma.

The contact structure 60 may include a metal plug 62, and a barrier metal layer 61 surrounding a bottom and side of the metal plug 62. The metal plug 62 may include metals such as tungsten, copper, nickel, cobalt, aluminum, titanium, and tantalum, and/or a metal compound such as metal nitride. The barrier metal layer 61 may include metals such as titanium (Ti), titanium nitride (TiN) tantalum (Ta), tantalum nitride (TaN), titanium tungsten (TiW), or other metals for barrier. For example, the barrier metal layer 61 may be in contact with the source/drain regions 50. For example, the barrier metal layer 61 may be in contact with the silicide region 53.

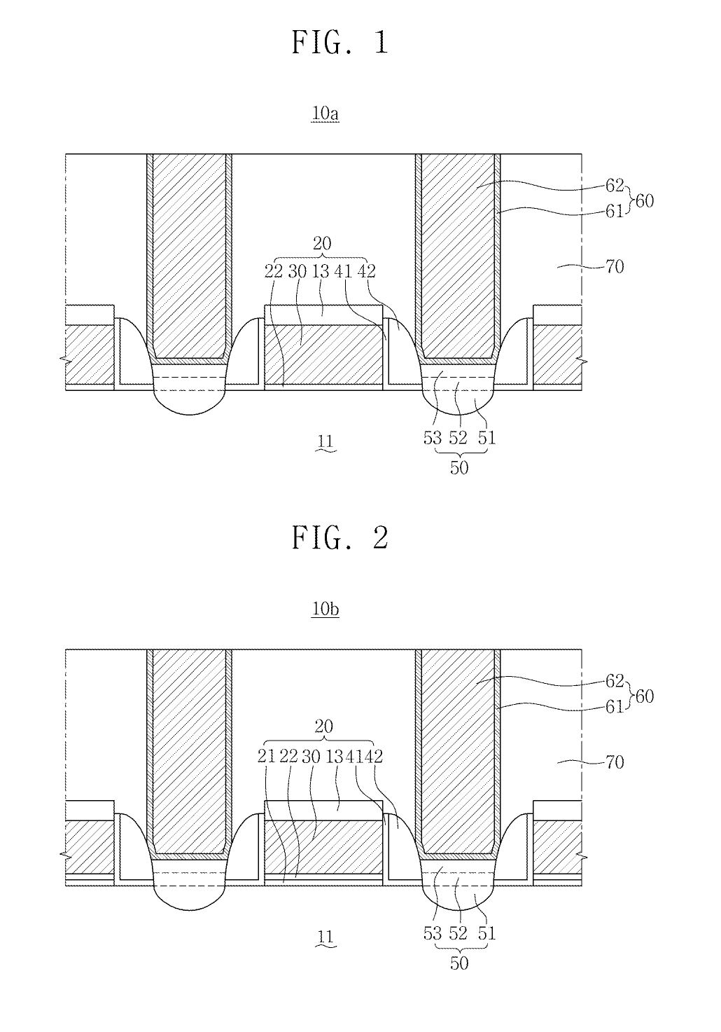

Referring to FIG. 2, a semiconductor device 10b according to another example embodiment may include a gate structure 20 formed on a substrate 11, source/drain regions 50 formed in the substrate 11, an interlayer insulating layer 70 covering the gate structure 20 and the source/drain regions 50, and a contact structure 60 vertically penetrating the interlayer insulating layer 70 to be in contact with the source/drain regions 50.

The gate structure 20 may include a surface insulating layer 21 directly formed on the substrate 11, a gate insulating layer 22 formed on the surface insulating layer 21, a gate electrode 30 formed on the gate insulating layer 22, an inner gate spacer 41 formed on sides of the gate insulating layer 22 and the gate electrode 30, and an outer gate spacer 42 formed on a side and surface of the inner gate spacer 41. The gate structure 20 may further include a hard mask pattern 13 formed on the gate electrode 30.

The surface insulating layer 21 may include oxidized silicon. For example, the surface insulating layer 21 may be formed by oxidizing the surface of the substrate 11.

The gate insulating layer 22 may include metal oxide such as hafnium oxide (HfO), lanthanum oxide (LaO), and aluminum oxide (AlO).

The gate electrode 30 may include metals such as tungsten, copper, nickel, cobalt, aluminum, titanium, and tantalum, and/or a metal compound such as metal nitride.

Further, other elements that are not described may be understood with reference to FIG. 1 and the description thereof.

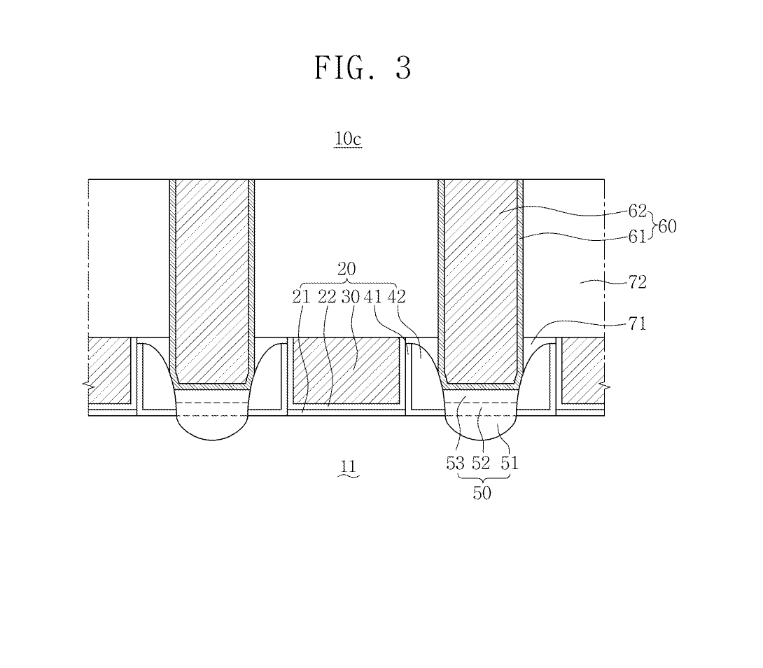

Referring to FIG. 3, a semiconductor device 10c according to another example embodiment may include a gate structure 20 formed on a substrate 11, source/drain regions 50 formed in the substrate 11, a lower interlayer insulating layer 71 covering the gate structure 20 and the source/drain regions 50, an upper interlayer insulating layer 72, and a contact structure 60 vertically penetrating the lower interlayer insulating layer 71 to be in contact with the source/drain regions 50.

The gate structure 20 may include a surface insulating layer 21 directly formed on the substrate 11, a gate insulating layer 22 formed on the surface insulating layer 21, a gate electrode 30 formed on the gate insulating layer 22, an inner gate spacer 41 formed on sides of the gate insulating layer 22 and the gate electrode 30, and an outer gate spacer 42 formed on a side and surface of the inner gate spacer 41. The gate insulating layer 22 may have a letter U-shape covering a bottom surface and side surfaces of the gate electrode 30. The gate insulating layer 22 may be in contact with the inner gate spacer 41. The gate insulating layer 22 may upwardly protrude from a top end of the inner gate spacer 41.

The semiconductor devices 10a to 10c according to various example embodiments may include an outer gate spacer 42 stacked as a multi-layer using remote plasma and formed using a plasma discharge process. Therefore, the semiconductor device 10a according to various example embodiments may include the outer gate spacer 42 having an improved profile and desirable electrical and material characteristics. When the outer gate spacer 42 is formed using a plasma discharge process, the gate electrode 30 and the inner gate spacer 41 may have an improved profile that is not damaged from an arcing or sparking phenomenon. Therefore, the semiconductor devices 10a to 10c according to various example embodiments can have improved electrical and physical stability and durability.

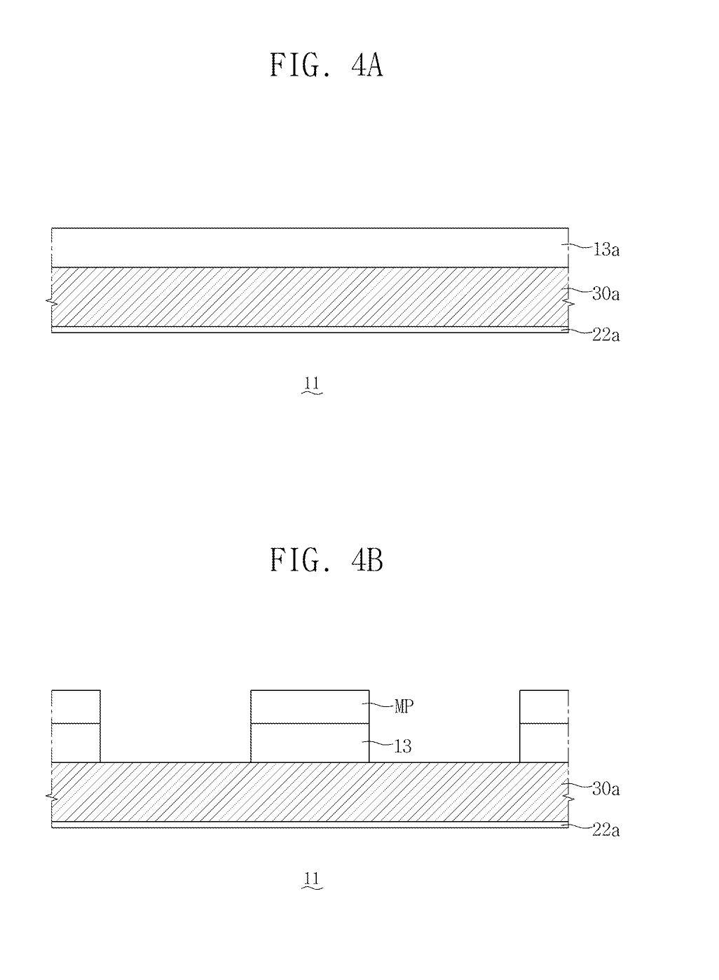

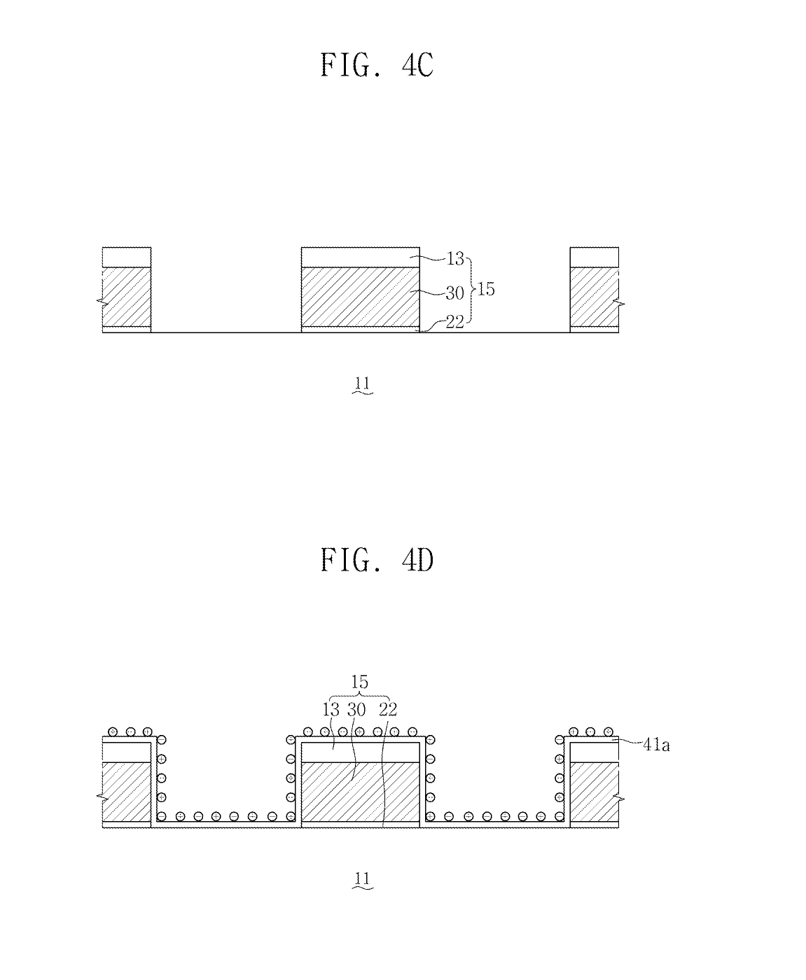

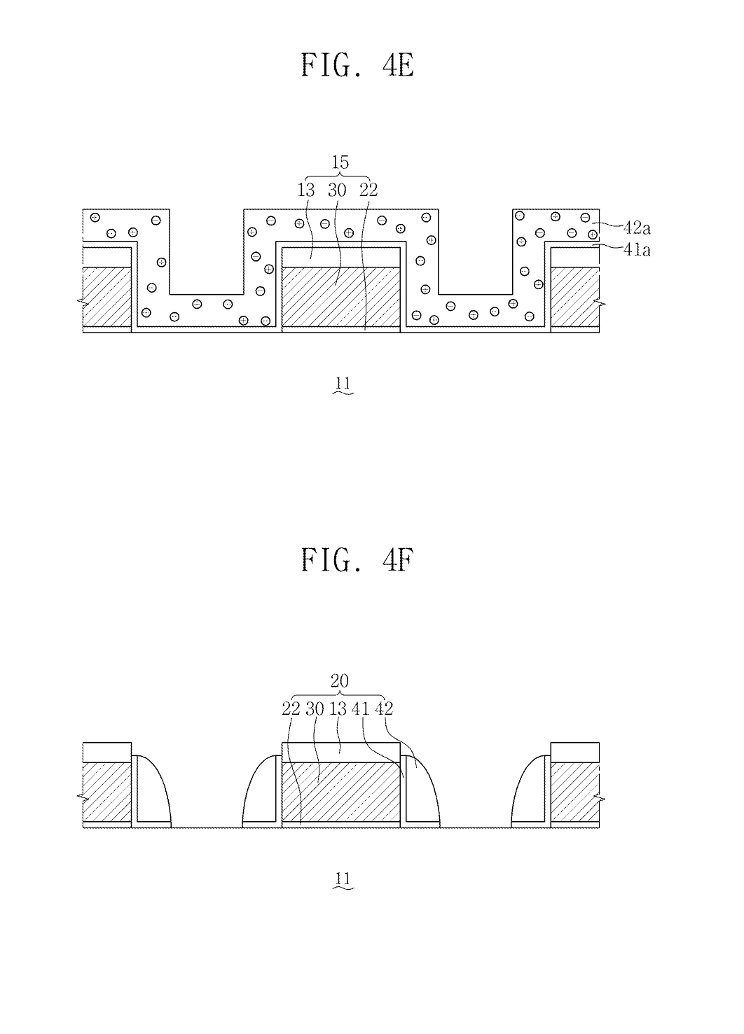

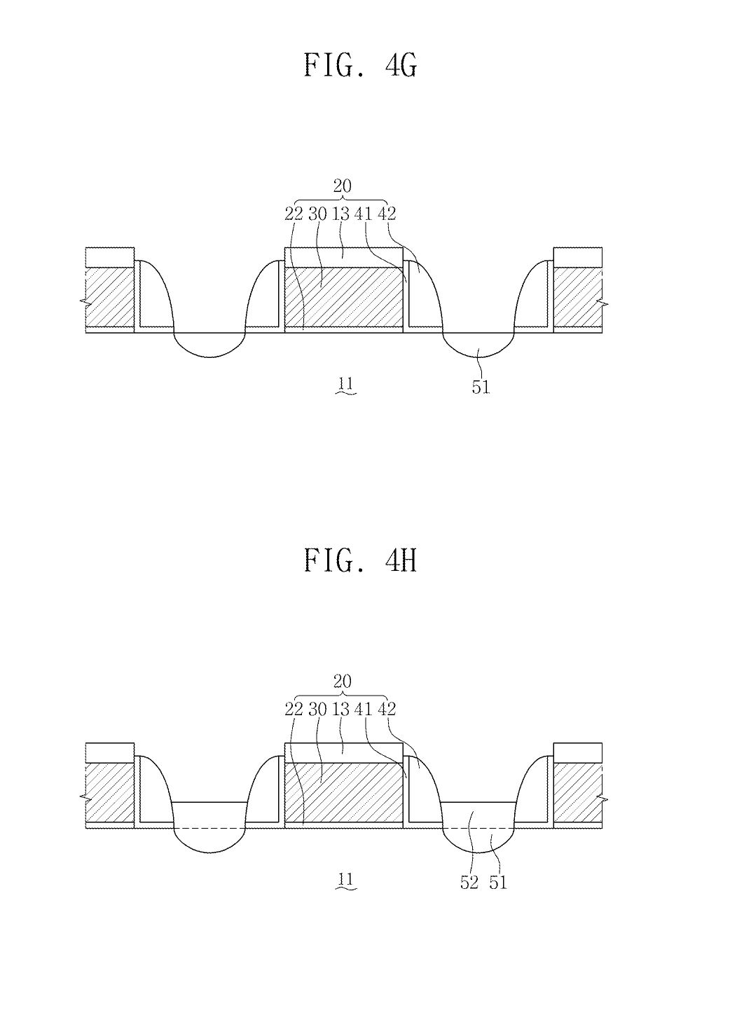

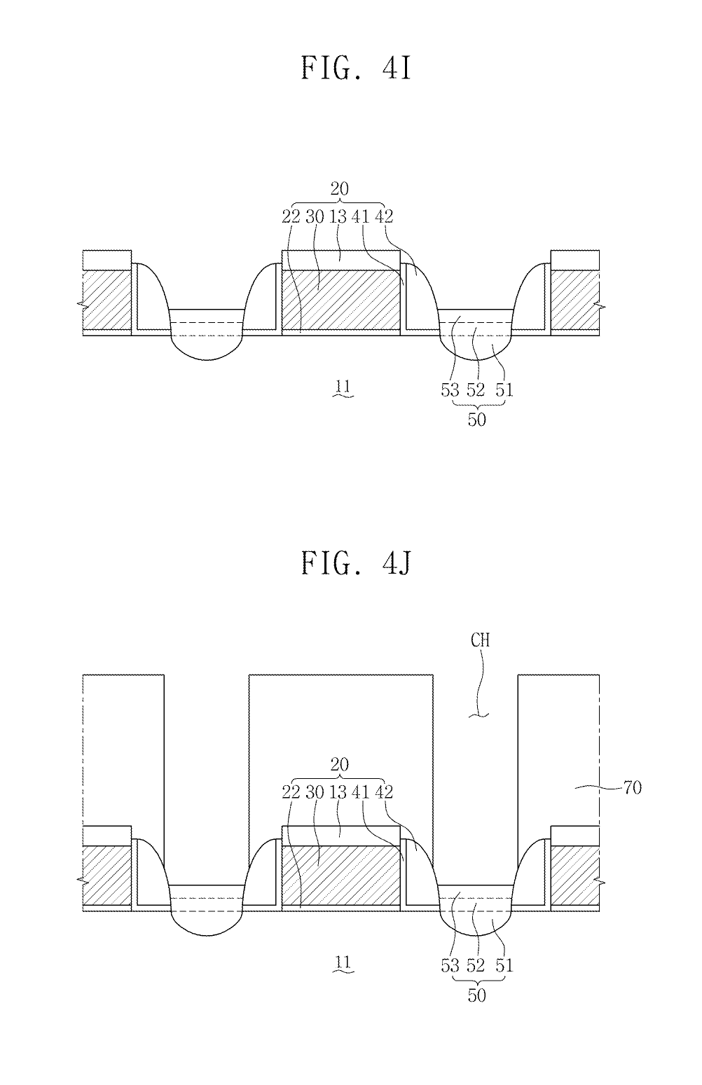

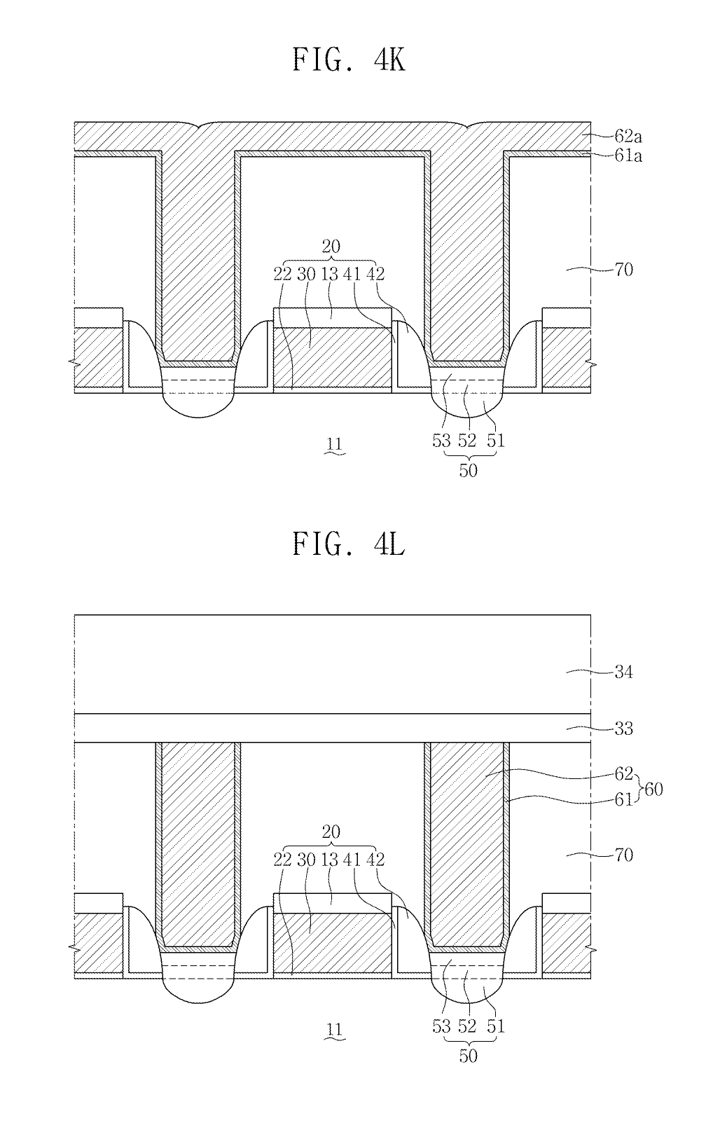

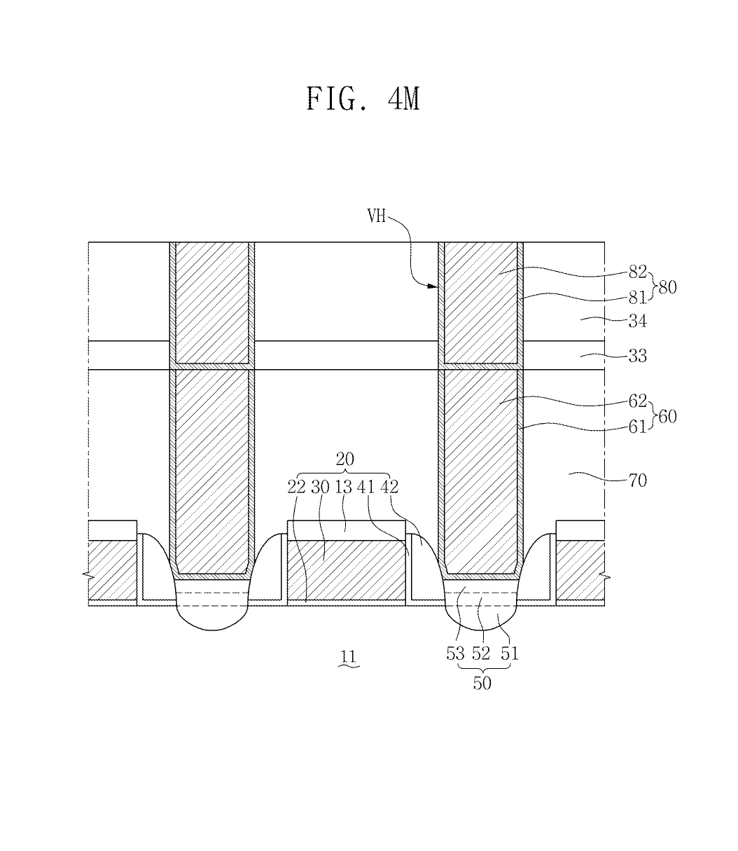

FIGS. 4A to 4M illustrate a method of fabricating a semiconductor device according to an example embodiment.

Referring to FIG. 4A, the method of fabricating a semiconductor device according to an example embodiment may include preparing a substrate 11, forming a gate insulating material layer 22a on the substrate 11, forming a gate electrode material layer 30a on the gate insulating material layer 22a, and forming a hard mask layer 13a on the gate electrode material layer 30a.

The substrate 11 may include a bulk silicon wafer or a silicon-on-insulator (SOI) wafer.

The gate insulating material layer 22a may be formed by forming oxidized silicon including oxidizing a surface of the substrate 11 using an oxidizing process.

The gate electrode material layer 30a may be formed by forming polysilicon on the gate insulating material layer 22a using a deposition process such as a CVD process.

The hard mask layer 13a may be formed by forming silicon nitride on the gate electrode material layer 30a using a deposition process such as a CVD process.

Referring to FIG. 4B, the method may include forming an etching mask pattern MP on the hard mask layer 13a, and patterning the hard mask layer 13a using the etching mask pattern MP as a patterning mask to form a hard mask pattern 13. Afterward, the etching mask pattern MP may be removed.

Referring to FIG. 4C, the method may include patterning the gate electrode material layer 30a and the gate insulating material layer 22a using the hard mask pattern 13 as a patterning mask to form a gate electrode 30 and a gate insulating layer 22. The hard mask pattern 13 may become thinner. During this process, an electrode structure 15 including the gate insulating layer 22, the gate electrode 30 and the hard mask pattern 13, may be formed.

Referring to FIG. 4D, the method may include forming an inner spacer material layer 41a covering surfaces of the substrate 11 and the gate electrode structure 15. For example, the inner spacer material layer 41a may conformally cover the surfaces of the substrate 11, sides of the gate insulating layer 22, sides of the gate electrode 30, and sides and top surfaces of the hard mask pattern 13. The inner spacer material layer 41a may be formed by forming silicon oxide by means of a PECVD process using inner plasma. The PECVD process may include generating plasma in a reaction chamber. For example, the inner spacer material layer 41a may be formed using a multi-layer deposition process such as an atomic layer deposition (ALD) process or a molecular layer deposition (MLD) process. During this process, charges (⊕/⊖) may accumulate on a surface of or in the inner spacer material layer 41a. The charges (⊕/⊖) may include ions and/or electrons.

Referring to FIG. 4E, the method of fabricating a semiconductor device according to an example embodiment may include conformally forming an outer spacer material layer 42a on the inner spacer material layer 41a. The outer spacer material layer 42a may include silicon nitride. The outer spacer material layer 42a may be formed by performing a multi-layer deposition process such as an ALD or MLD process to improve conformality. Furthermore, the ALD or MLD process may include a remote plasma process in which plasma is generated on the outside of the reaction chamber to be injected into the reaction chamber.

The remote plasma process may include a relatively small amount of ions and a relatively large amount of radicals different from an inner plasma process, and thus the material layer fowled using the remote plasma process may have a much lower charge than the material layer formed using the inner plasma process. For example, when the outer spacer material layer 42a is formed using the inner plasma process, the inner plasma sufficiently includes reactive ions and electrons, and thus the charges (⊕/⊖) accumulated on the surface of the inner spacer material layer 41a may disappear by their recombination.

However, when the outer spacer material layer 42a is formed using a remote plasma process, the content of ions is lowered, and thus the charges (⊕/⊖) accumulated during the previous plasma process may not be removed. Therefore, relatively high charges (⊕/⊖) may accumulate in the inner spacer material layer 41a and the outer spacer material layer 42a and/or on an interface therebetween. The accumulated charges (⊕/⊖) may cause an arcing or sparking phenomenon to occur in the subsequent processes, so that a pitting and/or migration phenomenon of the material layers may occur.

Referring to FIG. 4F, the method may include etching the outer spacer material layer 42a and the inner spacer material layer 41a using an etch-back process to form an outer gate spacer 42 and an inner gate spacer 41. An outer end portion of the outer gate spacer 42 may be vertically aligned with that of the inner gate spacer 41. For example, a surface of the substrate 11 may be exposed. A side of the hard mask pattern 13 disposed at a higher position than the top surface of the hard mask pattern 13 and a top end of the outer gate spacer 42 may be exposed. During this process, a gate structure 20 including the gate insulating layer 22, the gate electrode 30, the hard mask pattern 13, the inner gate spacer 41 and the outer gate spacer 42 may be formed.

The outer spacer material layer 42a may be formed by performing an etching process and a plasma discharge process. The etching process may include a first etching process having a relatively high etch selectivity, and a second etching process having a relatively low etch selectivity. The relatively high etch selectivity may refer to a high etch rate per time with respect to the outer spacer material layer 42a. Therefore, the first etching process may have a relatively etch rate per time with respect to the outer spacer material layer 42a than the second etching process.

For example, the first etching process having a relatively high etch rate may be performed using a gas containing carbon (C) and fluorine (F) such as CF₄, C₂F₆, C₃F₆, C₄F₈, etc., and the second etching process having a relatively low etch rate may be performed using a gas containing C, hydrogen (H) and F, for example, CHF₃. The first etching process exhibits a higher fluorine content than the second etching process.

The first etching process, the second etching process, and the plasma discharge process may form a cycle to be periodically repeated at least once. The one cycle process may be performed in-situ in the same chamber without vacuum break.

The plasma discharge process may be performed using an inert gas such as N₂, He and Ar, or a mixture thereof. For example, the plasma discharge process may include treating the inner spacer material layer and/or the outer spacer material layer by supplying N₂ gas or a mixture of N₂ gas and He gas to a vacuum chamber having a pressure of about 10 to 50 mTorr at a ratio of about 10:1 to 20:1 to excite the results into a plasma state.

Alternatively, the removal of the outer spacer material layer 42a may include performing an etching process and a plasma ion implantation process. The etching process may include a first etching process having a relatively high etch selectivity, and a second etching process having a relatively low etch selectivity.

The plasma ion implantation process may include a diffusion-type ion implantation process. For example, the diffusion-type ion implantation may include exciting P, As, B, H, C or N in a reaction chamber into a plasma state to diffuse the results into the outer spacer material layer 42a without using an implantation method.

The first etching process, the second etching process, and the plasma ion implantation process may form one cycle to periodically repeat the cycle at least once.

Referring to FIG. 4G, the method may include performing an ion implantation process using the gate structure 20 as an ion implantation mask to implant impurity atoms into the substrate 11, so that a lower source/drain region 51 is formed. The method may include implanting impurities such as P, As and B. The lower source/drain region 51 may be aligned with an outer end of the outer gate spacer 42.

Referring to FIG. 4H, the method may include ascending the surface of the substrate 11 in which the lower source/drain region 51 is formed. For example, a selective epitaxial growth process may be performed on the surface of the substrate 11, in which the lower source/drain region 51 is formed, to form an upper source/drain region 52 having an ascending surface.

Referring to FIG. 4I, the method may include forming a silicide region 53 in the upper source/drain regions 52. The silicide region 53 may be formed by forming a metal layer on the surface of the upper source/drain region 52 for a silicidation reaction, performing a silicidation process, and removing the metals that are not silicided. For example, the silicide region 53 may include nickel silicide, cobalt silicide, tungsten silicide, titanium silicide, or other metallic silicide. During this process, a source/drain region 50 including the lower source/drain region 51, the upper source/drain region 52 and the silicide region 53, may be formed.

Referring to FIG. 4J, the method may include forming an interlayer insulating layer 70 covering the gate structure 20, and forming a contact hole CH vertically penetrating the interlayer insulating layer 70 to expose a surface of the silicide region 53. The interlayer insulating layer 70 may be formed by performing a deposition process to form silicon oxide. The contact hole CH may partially expose the outer gate spacer 42.

Referring to FIG. 4K, the method may include conformally forming a barrier metal material layer 61a on an inner wall of the contact hole CH, and forming a plug metal layer 62a on the barrier metal material layer 61a to fill the contact hole CH. The barrier metal material layer 61a may include metals such as titanium (Ti), titanium nitride (TiN), tantalum (Ta), tantalum nitride (TaN), titanium tungsten (TiW), or other metals. The plug metal layer 62a may include metals such as tungsten, copper, nickel, cobalt, aluminum, titanium, and tantalum, and/or a metal compound such as metal nitride.

Referring to FIG. 4L, the method may include removing the barrier metal material layer 61a and the plug metal layer 62a on the interlayer insulating layer 70 using a CMP process to form a contact structure 60 having the barrier metal layer 61 and a metal plug 62, and forming a lower capping layer 33 and an upper capping layer 34 surrounding a side of the contact structure 60 with further reference to FIG. 1. The lower capping layer 33 may be formed by forming silicon oxide (SiOC) containing C by performing a deposition process. The upper capping layer 34 may be formed by forming silicon oxide by performing a deposition process.

Referring to FIG. 4M, the method may include forming a via structure 80 vertically penetrating the upper capping layer 34 and the lower capping layer 33 to be in contact with the contact structures 60. Referring further to FIGS. 4J to 4L, the via structures 80 may be formed by forming a via hole VH penetrating the upper capping layer 34 and the lower capping layer 33 to expose a top surface of the contact structure 60, conformally forming a via barrier metal layer 81 on an inner wall of the via hole VH, and forming a via plug 82 on the via barrier metal layer 81 to fill the via hole VH. The via barrier metal layer 81 may include metals such as Ti, TiN, Ta, TaN, and TiW, or another metal. The via plug 82 may include metals such as tungsten, copper, nickel, cobalt, aluminum, titanium, and tantalum, and/or a metal compound such as metal nitride. For example, the via barrier metal layer 81 may include the same material as the barrier metal layer 61 of the contact structure 60, and the via plug 82 may include the same material as the metal plug 62 of the contact structure 60.

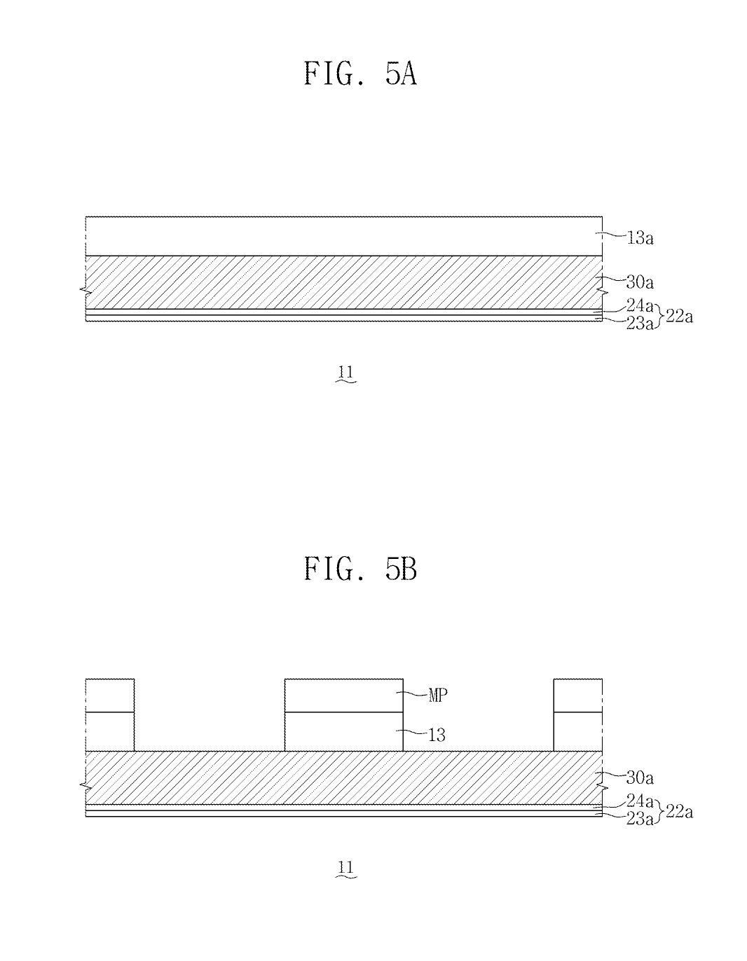

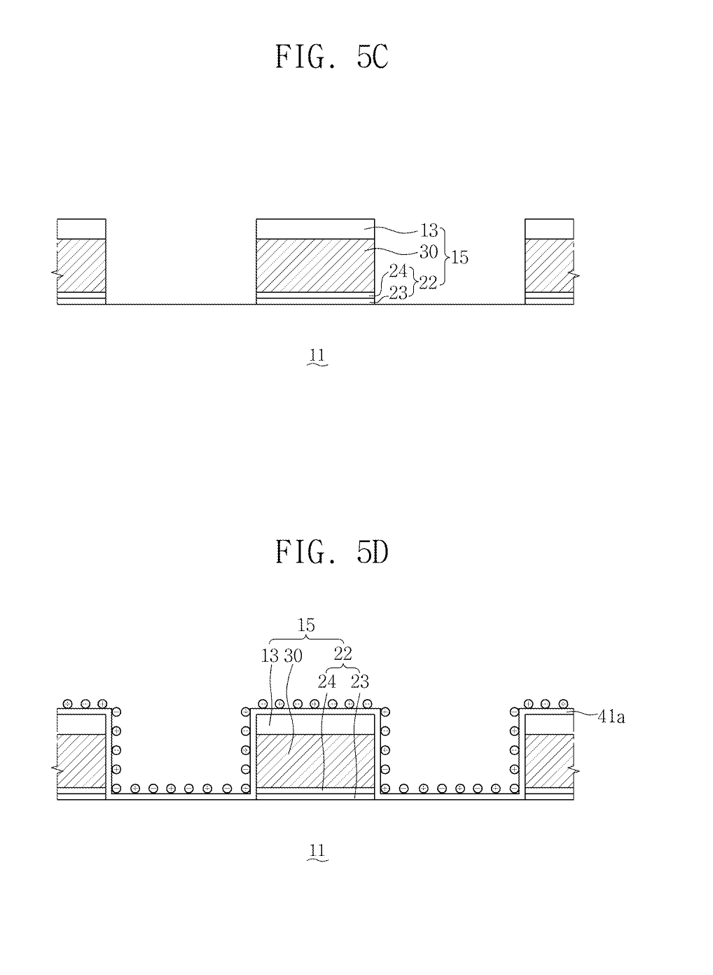

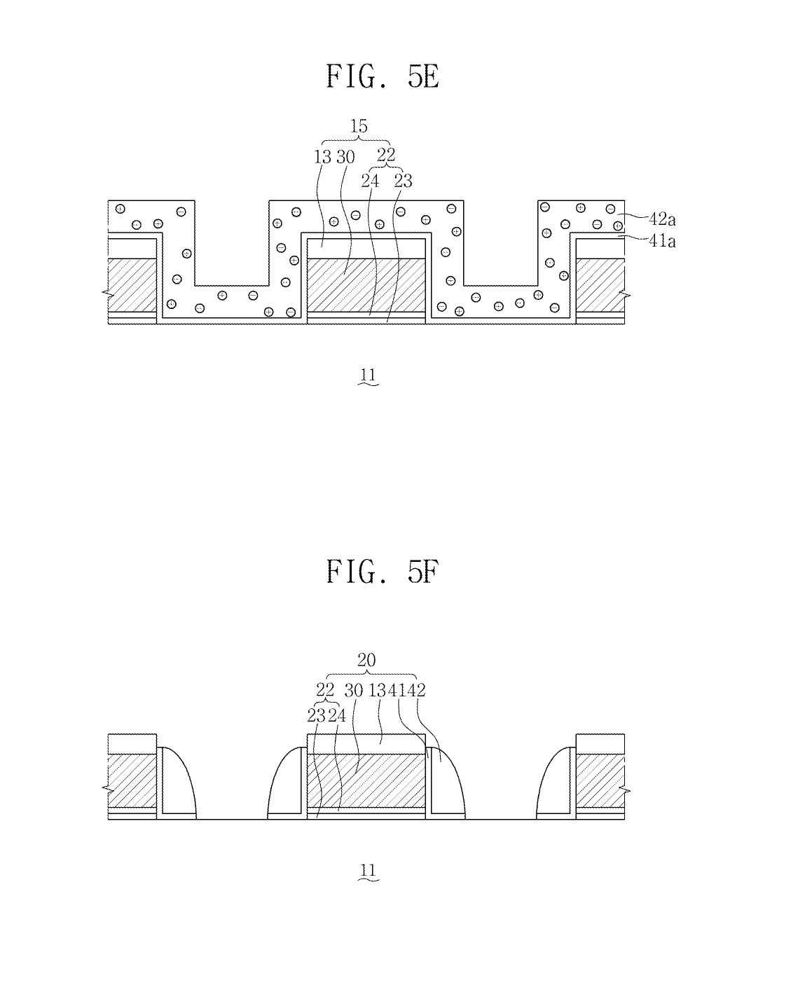

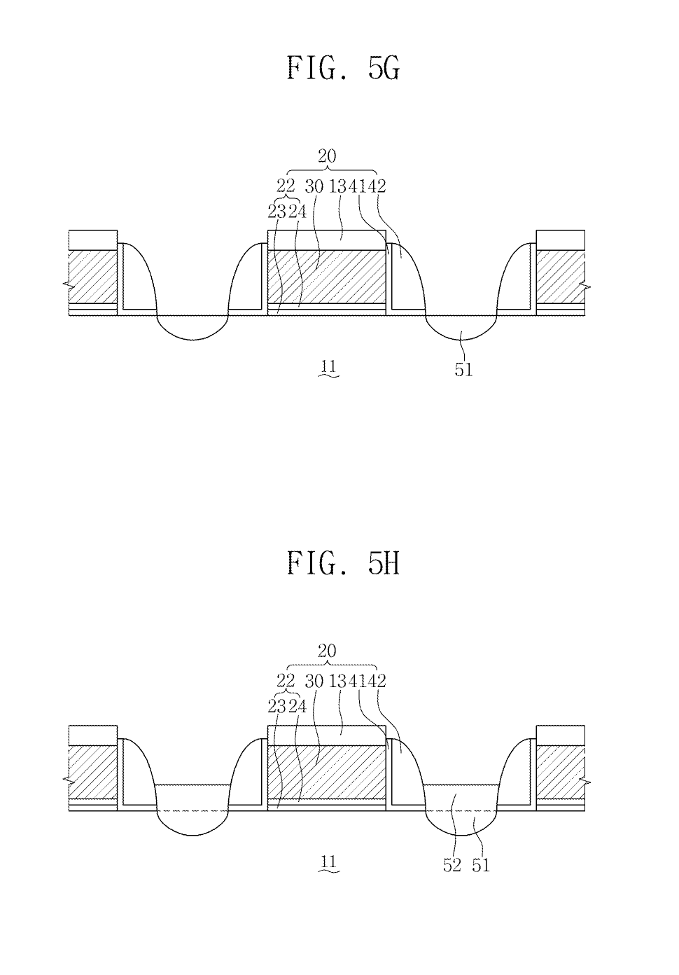

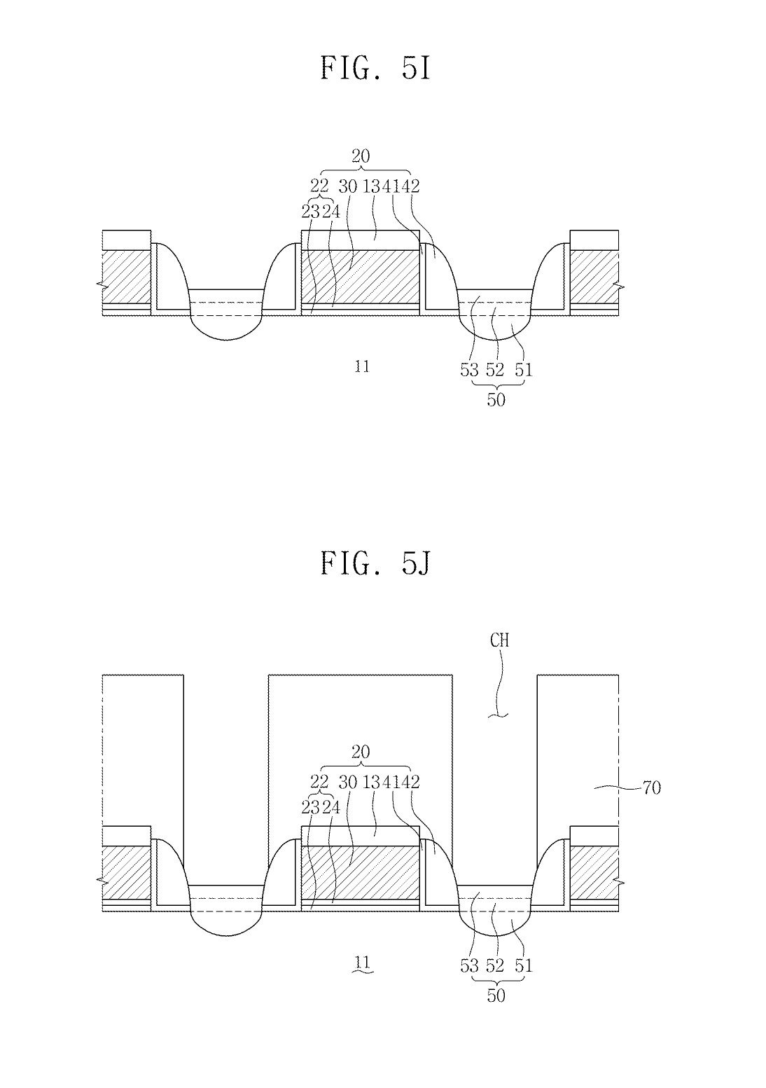

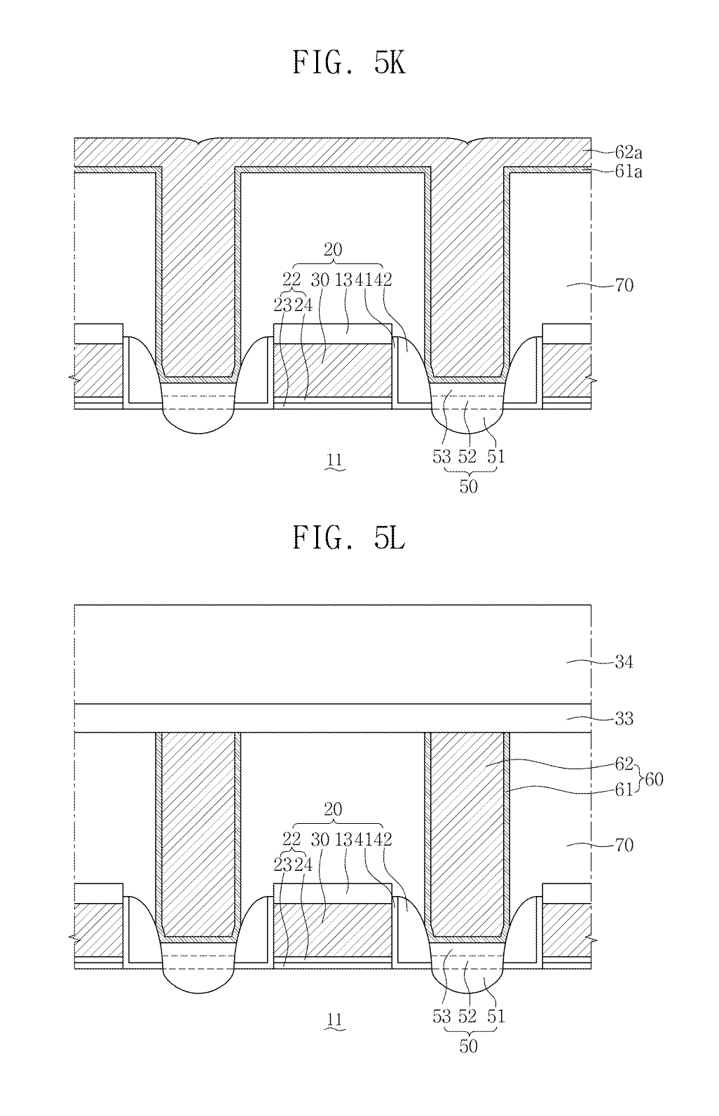

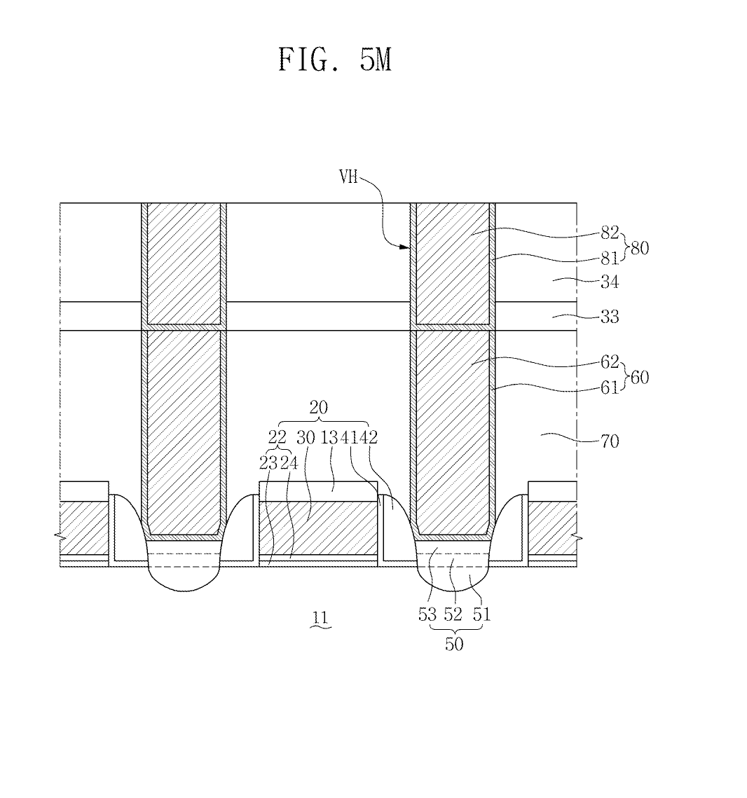

FIGS. 5A to 5M illustrate a method of fabricating a semiconductor device according to an example embodiment.

Referring to FIG. 5A, the method of fabricating a semiconductor device according to an example embodiment may include preparing a substrate 11, forming a gate insulating material layer 22a on a surface of the substrate 11, forming a gate electrode material layer 30a on the gate insulating material layer 22a, and forming a hard mask layer 13a on the gate electrode material layer 30a.

The gate insulating material layer 22a may be formed by directly forming the lower gate insulating material layer 23a on the substrate 11, and forming an upper gate insulating material layer 24a on the lower gate insulating material layer 23a.

The lower gate insulating material layer 23a may be formed by oxidizing a surface of the substrate 11 using an oxidizing process to form oxidized silicon, or forming silicon oxide using a deposition process such as CMP, ALD or MLD. The upper gate insulating material layer 24a may be formed by forming a metal oxide such as aluminum oxide (AlO), hafnium oxide (HfO), and lanthanum oxide (LaO) on the gate insulating material layer 23a using a deposition process such as CVD or physical vapor deposition (PVD).

The gate electrode material layer 30a may be formed by forming metals such as tungsten, copper, nickel, cobalt, aluminum, titanium, and tantalum, and/or a metal compound such as metal nitride. The gate electrode material layer 30a may be formed to be multi-layered.

The hard mask layer 13a may be formed by forming silicon nitride and/or silicon oxide on the gate electrode material layer 30a using a deposition process such as CVD.

Referring to FIG. 5B, the method may include forming an etching mask pattern MP on the hard mask layer 13a, and patterning the hard mask layer 13a using the etching mask pattern MP as a patterning mask to form a hard mask pattern 13. Afterward, the etching mask pattern MP may be removed.

Referring to FIG. 5C, the method may include patterning the gate electrode material layer 30a and the gate insulating material layer 22a using the hard mask pattern 13 as a patterning mask to form a gate electrode 30 and a gate insulating layer 22. The hard mask pattern 13 may become thinner. The gate insulating layer 22 may include a lower gate insulating layer 23 and an upper gate insulating layer 24. During this process, an electrode structure 15 including the gate insulating layer 22, the gate electrode 30 and the hard mask pattern 13 may be formed.

Referring to FIG. 5D, the method may include forming an inner spacer material layer 41a covering the surface of the substrate 11 and the surface of the gate electrode structure 15. For example, the inner spacer material layer 41a may conformally cover the surfaces of the substrate 11, sides of the gate insulating layer 22, sides of the gate electrode 30, and sides and upper surfaces of the hard mask pattern 13. The inner spacer material layer 41a may be formed by forming silicon oxide by means of a PE-CVD process using inner plasma. For example, the inner spacer material layer 41a may be formed using a multi-layer deposition process such as an ALD or MLD process. During this process, charges (⊕/⊖) may accumulate on a surface of or in the inner spacer material layer 41a. The charges (⊕/⊖) may include ions and/or electrons.

Referring to FIG. 5E, the method may include conformally forming an outer spacer material layer 42a on an inner spacer material layer 41a. The outer spacer material layer 42a may include silicon nitride. The outer spacer material layer 42a may be formed by performing a multi-layer deposition process such as an ALD or MLD process using a remote plasma process to improve conformality. The remote plasma process may include generating plasma on the outside of the reaction chamber to be injected into the reaction chamber. The outer spacer material layer 42a may include silicon nitride. In addition, the ALD or MLD process for forming the outer spacer material layer 42a may include a remote plasma process.

Referring to FIG. 5F, the method may include etching the outer spacer material layer 42a and the inner spacer material layer 41a using an etch-back process to form an outer gate spacer 42 and an inner gate spacer 41. During this process, a gate structure 20 including the gate insulating layer 22, the gate electrode 30, the hard mask pattern 13, the inner gate spacer 41 and the outer gate spacer 42, may be formed. The gate insulating layer 22 may include a lower gate insulating layer 23 and an upper gate insulating layer 24.

The outer spacer material layer 42a may be removed by performing an etching process and a plasma discharge process. The etching process may include a first etching process having a relatively high etch selectivity, and a second etching process having a relatively low etch selectivity. The first etching process, the second etching process, and the plasma discharge process may form a cycle to be periodically repeated at least once.

Alternatively, the outer spacer material layer 42a may be removed by performing an etching process and a plasma ion implantation process. The etching process may include a first etching process having a relatively high etch selectivity, and a second etching process having a relatively low etch selectivity. The plasma ion implantation process may include a diffusion-type ion implantation process. The first etching process, the second etching process, and the plasma ion implantation process may form a cycle to be periodically repeated at least once.

Referring to FIG. 5G, the method may include performing an ion implantation process using the gate structure 20 as an ion implantation mask to implant impurity atoms into the substrate 11, so that a lower source/drain region 51 is formed.

Referring to FIG. 5H, the method may form an upper source/drain region 52 on the lower source/drain region 51. The upper source/drain region 52 may be formed by performing a selective epitaxial growth process.

Referring to FIG. 5I, the method may include forming a silicide region 53 in the upper source/drain regions 52. During this process, source/drain regions 50 including the lower source/drain region 51, the upper source/drain region 52 and the silicide region 53 may be formed.

Referring to FIG. 5J, the method may include forming an interlayer insulating layer 70 covering the gate structure 20, and vertically penetrating the interlayer insulating layer 70 to form a contact hole CH exposing a surface of the silicide region 53.

Referring to FIG. 5K, the method may include conformally forming a barrier metal material layer 61a on an inner wall of the contact hole CH, and forming a plug metal layer 62a on the metal layer 61a to fill the contact hole CH.

Referring to FIG. 5L, the method may include removing the barrier metal material layer 61a and the plug metal layer 62a on the interlayer insulating layer 70 using a CMP process to form a contact structure 60 having a barrier metal layer 61 and a metal plug 62, and forming a lower capping layer 33 and an upper capping layer 34 surrounding sides of the contact structure 60 on the interlayer insulating layer 70 with further reference to FIG. 2. The lower capping layer 33 may be formed by forming silicon oxide (SiOC) containing C by a deposition process. The upper capping layer 34 may be formed by forming silicon oxide by a deposition process.

Referring to FIG. 5M, the method may include forming a via structure 80 vertically penetrating the upper capping layer 34 and the lower capping layer 33 to be in contact with the contact structures 60. Referring further to FIGS. 5J to 5L, the via structures 80 may be formed by forming a via hole VH penetrating the upper capping layer 34 and the lower capping layer 33 to expose a top surface of the contact structure 60, conformally forming a via barrier metal layer 81 on an inner wall of the via hole VH, and forming a via plug 82 on the via barrier metal layer 81 to fill the via hole VH.

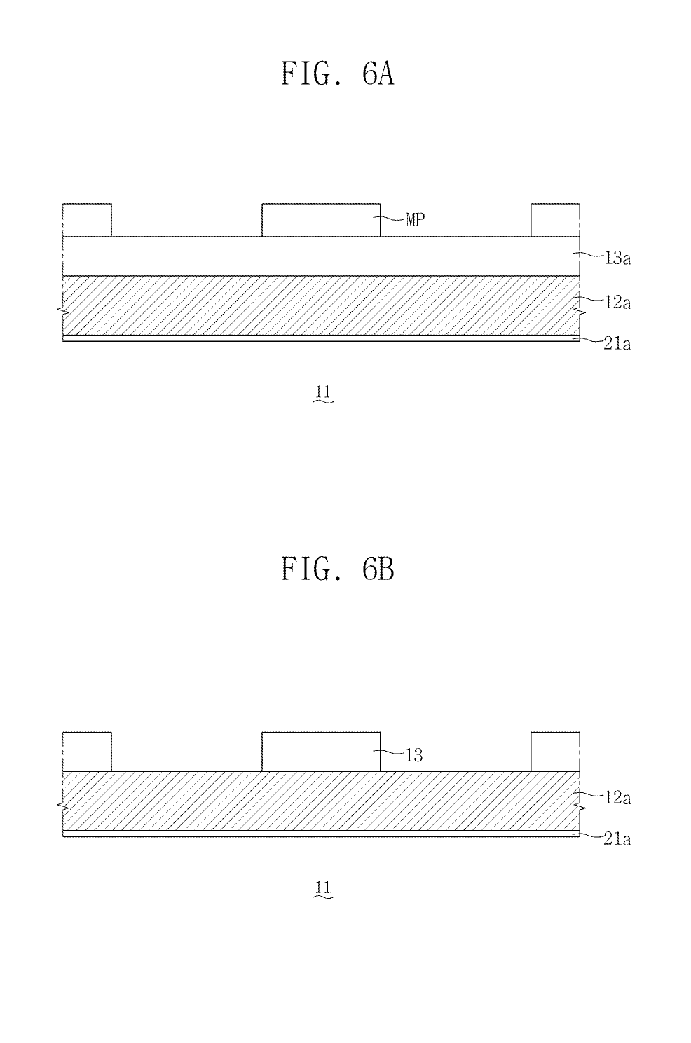

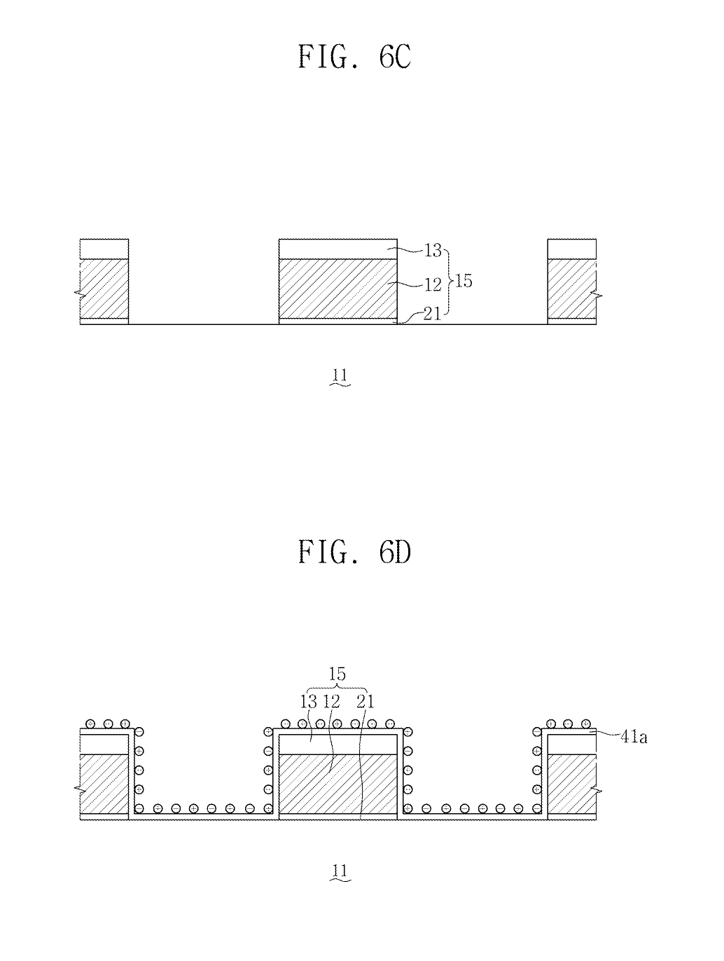

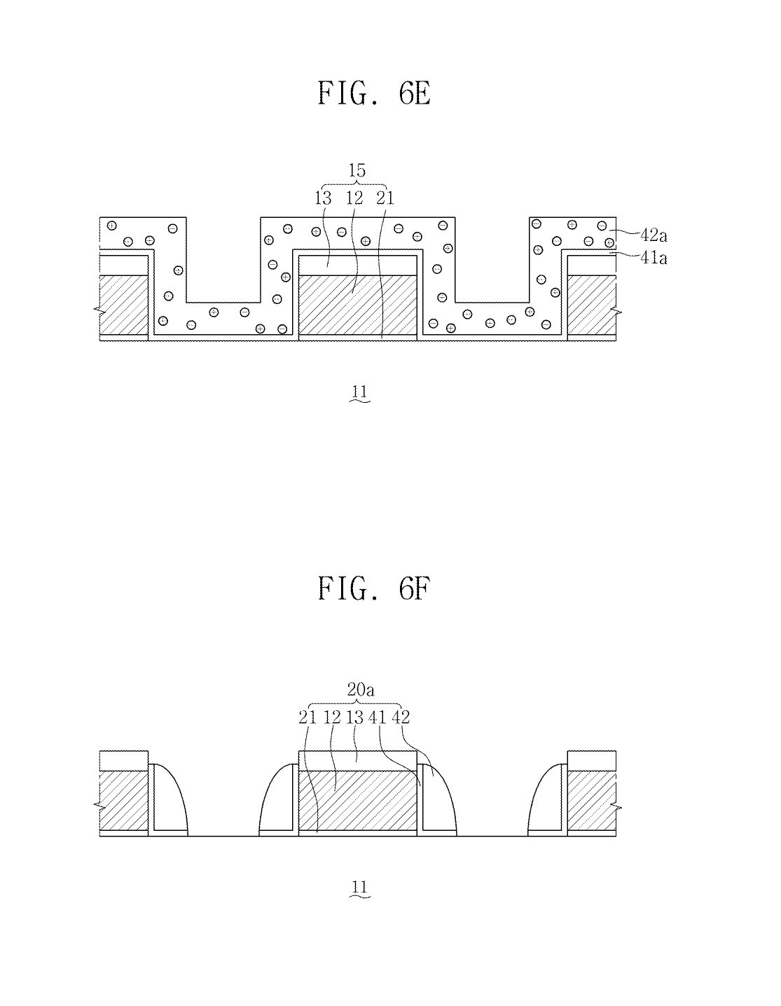

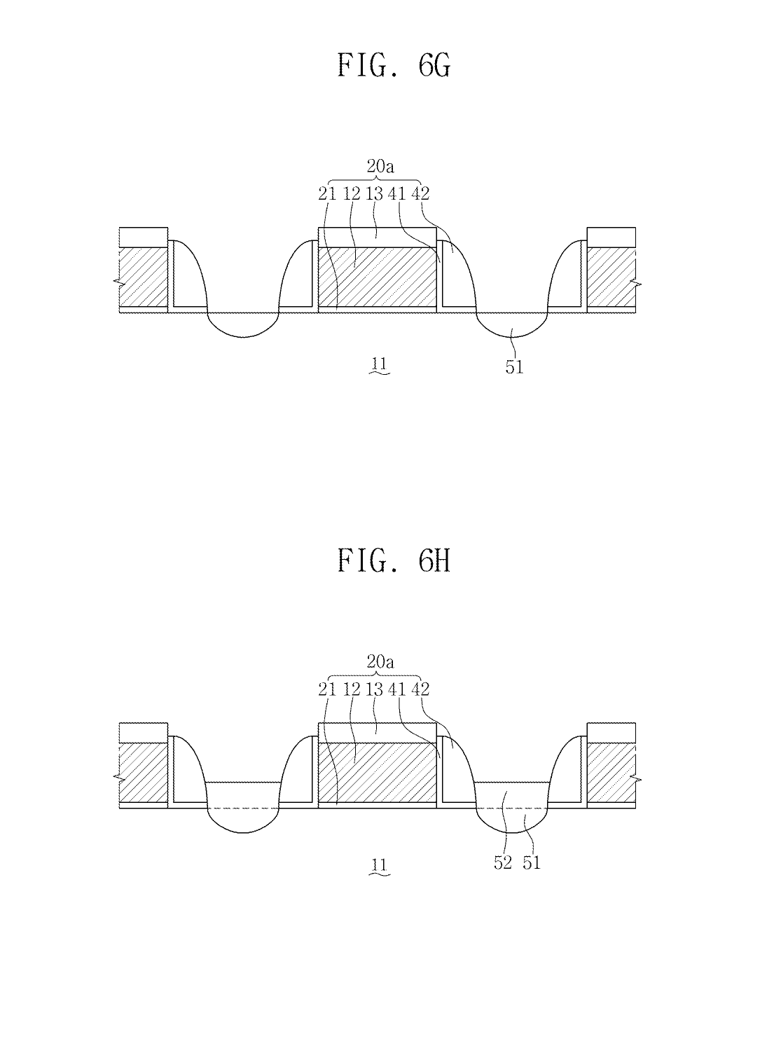

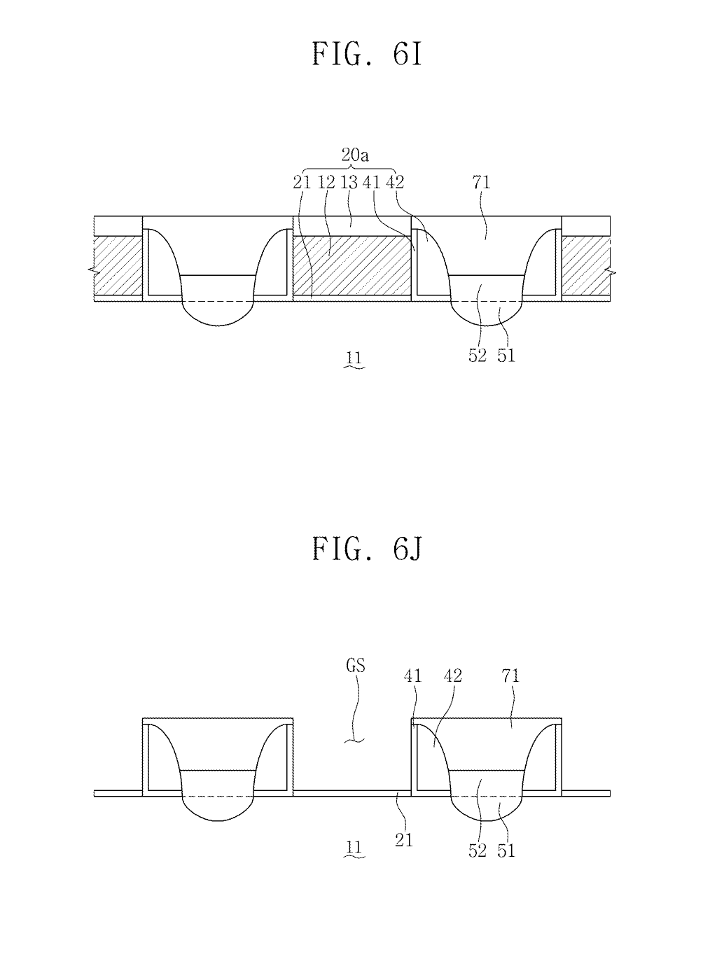

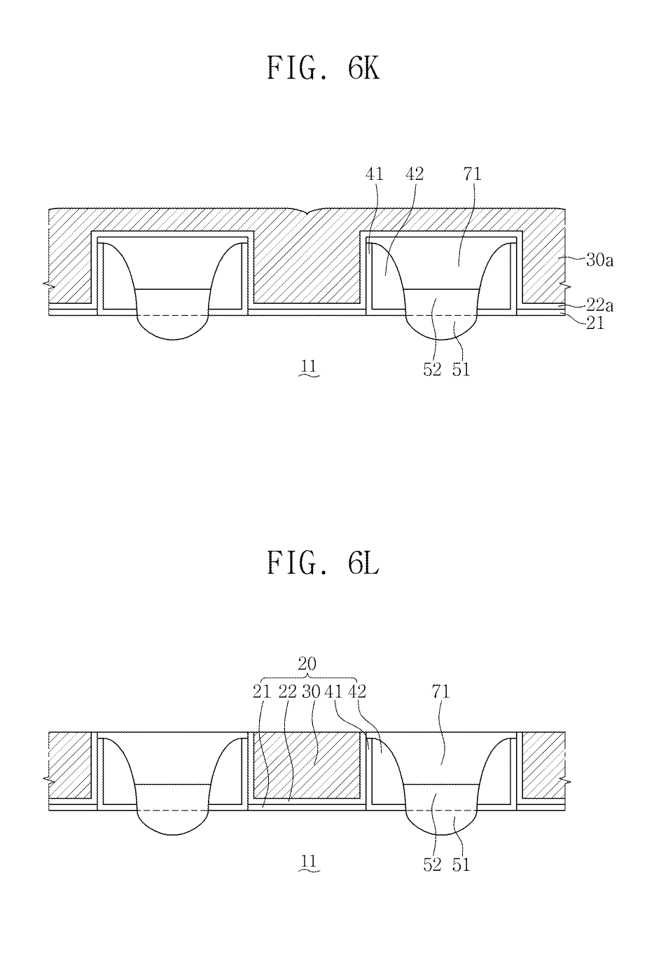

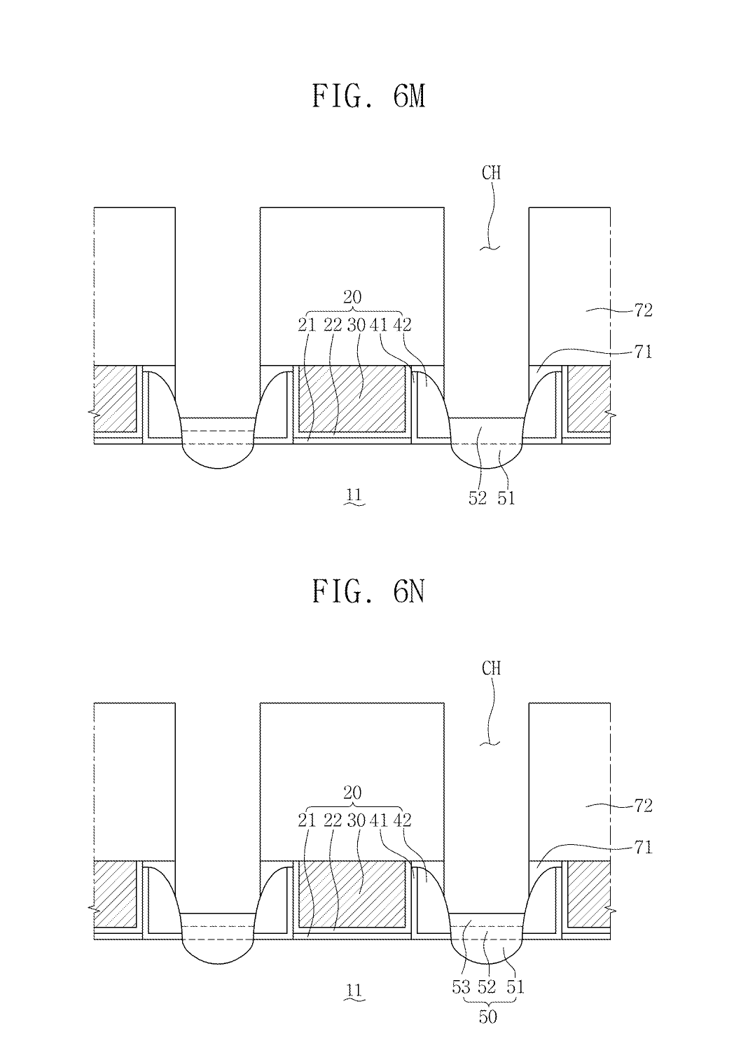

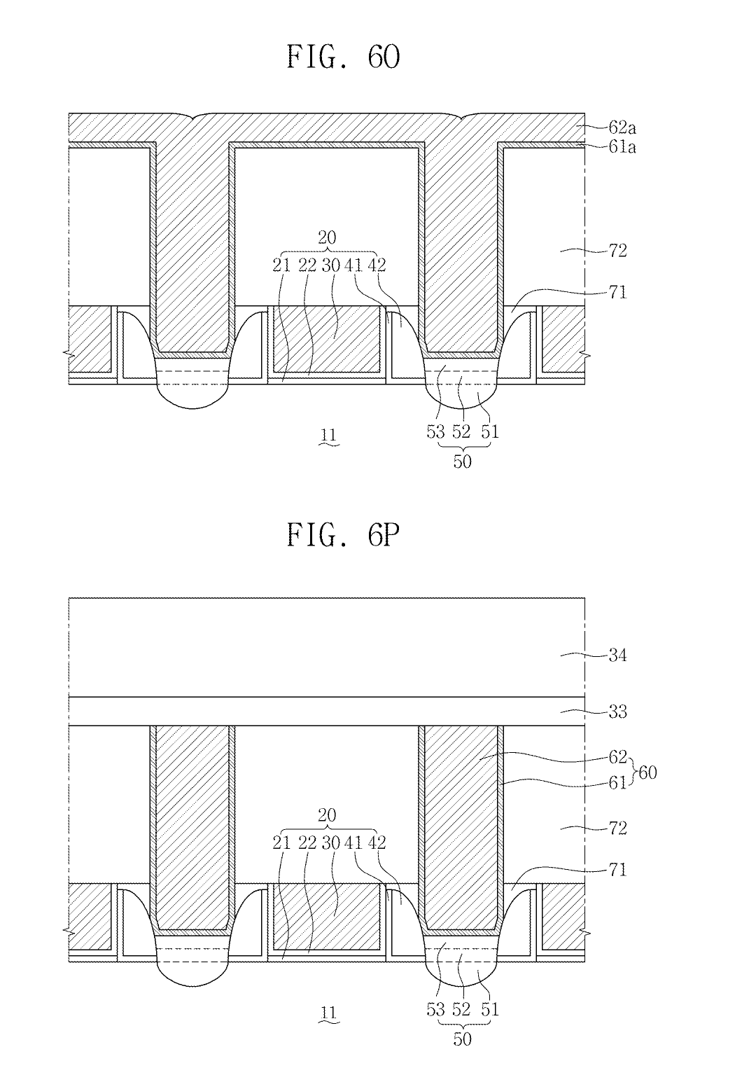

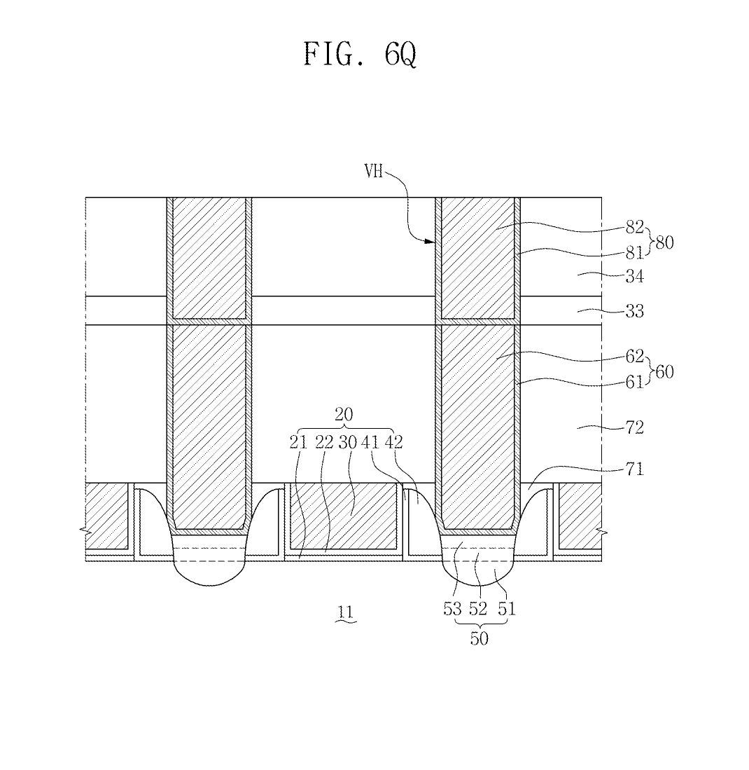

FIGS. 6A to 6Q illustrate a method of fabricating a semiconductor device according to an example embodiment.

Referring to FIG. 6A, the method of fabricating a semiconductor device according to an example embodiment may include preparing a substrate 11, forming a surface insulating material layer 21a on a surface of the substrate 11, forming a sacrificial material layer 12a on the surface insulating material layer 21a, forming a hard mask layer 13a on the sacrificial material layer 12a, and forming an etching mask pattern MP on the hard mask layer 13a. The substrate 11 may include a bulk silicon wafer or a silicon on insulator (SOI) wafer. The surface insulating material layer 21a may be formed by oxidizing the surface of the substrate 11 using an oxidizing process to form oxidized silicon. The sacrificial material layer 12a may be formed by forming polysilicon on the surface insulating material layer 21a using a deposition process such as a CVD process. The hard mask layer 13a may be formed by forming silicon nitride on the sacrificial material layer 12a using a deposition process such as a CVD process. The etching mask pattern MP may be formed by forming a photoresist pattern using a photolithography process.

Referring to FIG. 6B, the method may include patterning the hard mask layer 13a using the etching mask pattern MP as a patterning mask to form a hard mask pattern 13, and removing the etching mask pattern MP.

Referring to FIG. 6C, the method may include patterning the surface insulating material layer 21a and the sacrificial material layer 12a using the hard mask pattern 13 as a patterning mask to form a sacrificial pattern 12 and a surface insulating layer 21. The hard mask pattern 13 may become thinner. During this process, an electrode structure 15 including the surface insulating layer 21, the sacrificial pattern 12 and the hard mask pattern 13 may be formed.

Referring to FIG. 6D, the method may include may include forming an inner spacer material layer 41a covering the surface of the substrate 11 and the surface of the gate electrode structure 15. For example, the inner spacer material layer 41a may conformally cover the surfaces of the substrate 11, sides of the surface insulating layer 21, sides of the sacrificial pattern 12, and side and top surfaces of the hard mask pattern 13. The inner spacer material layer 41a may be formed by forming silicon oxide by means of a CVD process using an inner plasma process. For example, the inner spacer material layer 41a may be formed using a multi-layer deposition process such as an ALD process or a MLD process. During this process, charges (⊕/⊖) may accumulate on a surface of or in the inner spacer material layer 41a. The charges (⊕/⊖) may include ions and/or electrons.

Referring to FIG. 6E, the method may include conformally forming an outer spacer material layer 42a on an inner spacer material layer 41a. The outer spacer material layer 42a may be formed by performing a multi-layer deposition process such as an ALD or MLD process to improve conformality. The outer spacer material layer 42a may include silicon nitride. In addition, the ALD or MLD process may include a remote plasma process.

Referring to FIG. 6F, the method may include may include etching the outer spacer material layer 42a and the inner spacer material layer 41a using an etch-back process to form an outer gate spacer 42 and an inner gate spacer 41. An outer end portion of the outer gate spacer 42 may be vertically aligned with that of the inner gate spacer 41. For example, a surface of the substrate 11 may be exposed. A side of the hard mask pattern 13 disposed at a higher position than the top surface of the hard mask pattern 13 and a top end of the outer gate spacer 42 may be exposed. During this process, a preliminary gate structure 20a including the surface insulating layer 21, the sacrificial pattern 12, the hard mask pattern 13, the inner gate spacer 41 and the outer gate spacer 42 may be formed.

The outer spacer material layer 42a may be removed by performing an etching process and a plasma discharge process. The etching process may include a first etching process having a relatively high etch selectivity, and a second etching process having a relatively low etch selectivity. The first etching process, the second etching process, and the plasma discharge process may form a cycle to be periodically repeated at least once.

Alternatively, the outer spacer material layer 42a may be removed by performing an etching process and a plasma ion implantation process. The etching process may include a first etching process having a relatively high etch selectivity, and a second etching process having a relatively low etch selectivity. The plasma ion implantation process may include a diffusion-type ion implantation process. The first etching process, the second etching process, and the plasma ion implantation process may form one cycle to periodically repeat the cycle at least once.

Referring to FIG. 6G, the method may include performing an ion implantation process using the preliminary gate structure 20a as an ion implantation mask to implant impurity atoms into the substrate 11, so that a lower source/drain region 51 is formed. The lower source/drain region 51 may be aligned with an outer end of the outer gate spacer 42.

Referring to FIG. 6H, the method may include formng an upper source drain region 52 on the lower source/drain region 51. The upper source/drain region 52 may be formed by performing a selective epitaxial growth process.

Referring to FIG. 6I, the method may include forming a lower interlayer insulating layer 71 covering the preliminary gate structure 20a and the upper source/drain region 52, and removing an upper part of the lower interlayer insulating layer 71 using a CMP process to expose the hard mask pattern 13.

Referring to FIG. 6J, the method may include removing the hard mask pattern 13 and the sacrificial pattern 12 to define a gate electrode space GS. The hard mask pattern 13 may be removed by performing a wet process using phosphoric acid (H₃PO₄). The sacrificial pattern 12 may be removed by performing a dry etching process using chlorine ions (Cl−) or chlorine radicals (Cl*). The gate electrode space GS may be defined by the surface insulating layer 21 and the inner gate spacer 41.

Referring to FIG. 6K, the method may include forming a gate insulating material layer 22a and a gate electrode material layer 30a in the gate electrode space (GS). The gate insulating material layer 22a may be formed by forming metal oxide such as HfO, LaO, and AlO on the surface insulating layer 21 using a deposition process such as CVD or PVD. The gate electrode material layer 30a may be formed by forming metals such as tungsten, copper, nickel, cobalt, aluminum, titanium, and tantalum, and/or a metal compound such as metal nitride on the gate insulating material layer 22a.

Referring to FIG. 6L, the method may include removing the gate electrode material layer 30a and the gate insulating material layer 22a on the lower interlayer insulating layer 71 using a CMP process to form a gate insulating layer 22 and a gate electrode 30. The gate insulating layer 22 may cover a bottom and side of the gate electrode 30. During this process, a gate structure 20 including the surface insulating layer 21, the gate insulating layer 22, the gate electrode 30, the inner gate spacer 41 and the outer gate spacer 42, may be formed.

Referring to FIG. 6M, the method may include forming an upper interlayer insulting layer 72 on the lower interlayer insulating layer 71 and the gate structure 20, and forming a contact hole CH vertically penetrating the upper interlayer insulting layer 72 and the lower interlayer insulating layer 71 to expose the upper source/drain regions 52.

Referring to FIG. 6N, the method may include forming a silicide region 53 in the upper source/drain regions 52 exposed in the contact hole CH. During this process, a source/drain region 50 including the lower source/drain region 51, the upper source/drain region 52 and the silicide region 53 may be formed.

Referring to FIG. 6O, the method may include conformally forming a barrier metal material layer 61a on an inner wall of the contact hole CH and a surface of the silicide region 53, and forming a plug metal layer 62a on the barrier metal material layer 61a to fill the contact hole CH.

Referring to FIG. 6P, the method may include removing the barrier metal material layer 61a and the plug metal layer 62a on the upper interlayer insulating layer 72 using a CMP process to form a contact structure 60 having a barrier metal layer 61 and a metal plug 62, and forming a lower capping layer 33 and an upper capping layer 34 surrounding sides of the contact structure 60 on the upper interlayer insulating layer 72 with further reference to FIG. 3. The lower capping layer 33 may be formed by forming SiOC containing C by a deposition process. The upper capping layer 34 may be formed by forming silicon oxide by a deposition process.

Referring to FIG. 6Q, the method may include forming a via structure 80 vertically penetrating the upper capping layer 34 and the lower capping layer 33 to be in contact with the contact structures 60. Referring further to FIGS. 6M to 6P, the via structures 80 may be formed by forming a via hole VH penetrating the upper capping layer 34 and the lower capping layer 33 to expose a top surface of the contact structure 60, conformally forming a via barrier metal layer 81 on an inner wall of the via hole VH, and forming a via plug 82 on the via barrier metal layer 81 to fill the via hole VH.

The methods of fabricating semiconductor devices according to various example embodiments may include stacking and forming the outer gate spacer 42 to be multi-layered using a plasma discharge process. Therefore, according to the methods of fabricating a semiconductor device according to various example embodiments, the gate electrode 30 and the inner gate spacer 41 may have an improved profile that is not damaged from an arcing or sparking phenomenon caused by accumulated charges. Therefore, according to the methods of fabricating a semiconductor device according to various example embodiments, a semiconductor device having improved electrical and physical stability and durability may be fabricated.

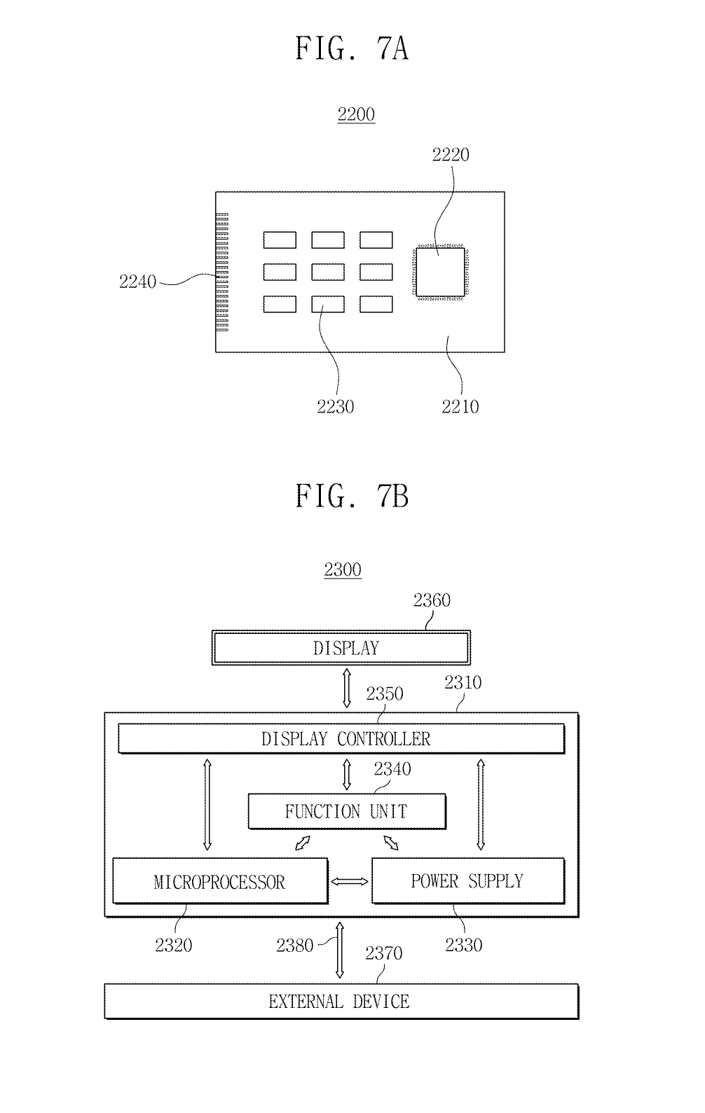

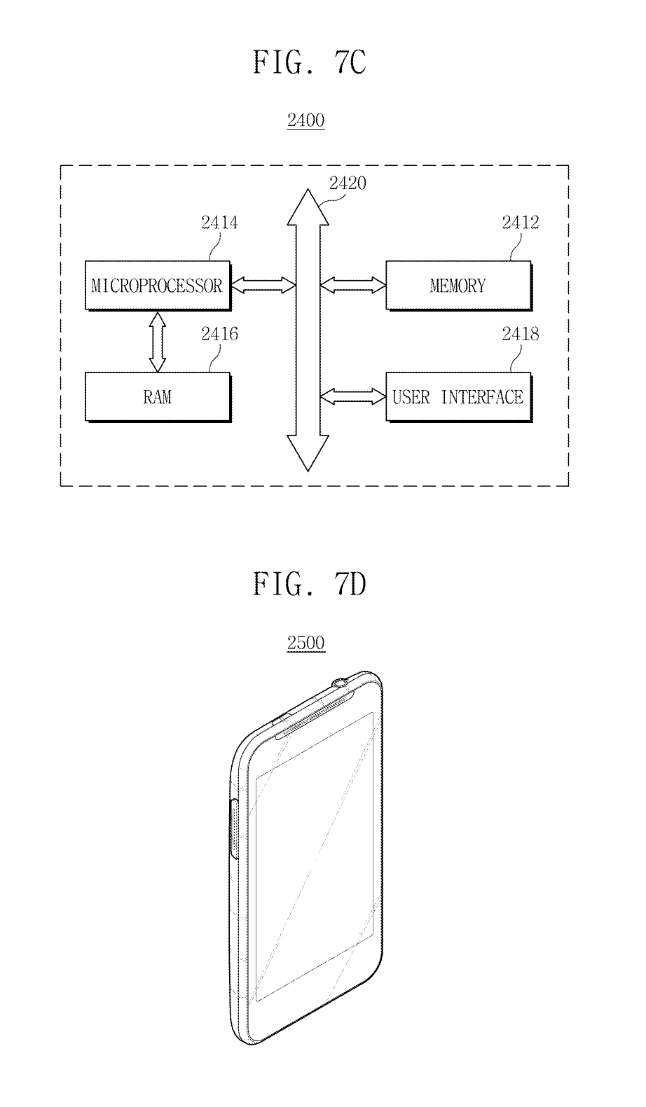

FIG. 7A is a schematic view of a semiconductor module 2200 including at least one of semiconductor devices 10a to 10c according to various example embodiments. Referring to FIG. 7A, a semiconductor module 2200 according to an example embodiment may include one of the semiconductor devices 10a to 10c according to various example embodiments mounted on a semiconductor module substrate 2210. The semiconductor module 2200 may further include a microprocessor 2220 mounted on the module substrate 2210. Input/output terminals 2240 may be disposed on (in) at least one corner of the module substrate 2210. The microprocessor 2220 may include one of the semiconductor devices 10a to 10c according to example embodiments.

FIG. 7B is a conceptual block diagram of an electronic system 2300 including at least one of the semiconductor devices 10a to 10c according to various example embodiments. Referring to FIG. 7B, the semiconductor devices 10a to 10c according to various example embodiments may be applied to the electronic system 2300. The electronic system 2300 may include a body 2310. The body 2310 may include a microprocessor unit 2320, a power supply unit 2330, a function unit 2340, and/or a display controller unit 2350. The body 2310 may be a system board or main board formed of a PCB or the like. The microprocessor unit 2320, the power supply unit 2330, the function unit 2340 and the display controller unit 2350 may be mounted or installed on the body 2310. A display unit 2360 may be mounted on or outside the body 2310. For example, the display unit 2360 may be disposed on a surface of the body 2310 to display an image processed by the display controller unit 2350. The power supply unit 2330 is supplied with a given (or, alternatively predetermined) voltage from an external power supply, and divides the voltage into a required voltage level to supply to the microprocessor unit 2320, the function unit 2340 and the display controller unit 2350. The microprocessor unit 2320 may be supplied with a voltage from the power supply unit 2330 to control the functional unit 2340 and the display unit 2360.

The function unit 2340 may perform various functions of the electronic system 2300. For example, when the electronic system 2300 is a mobile electronic product such as a cellular phone, the functional unit 2340 may include various components capable of performing wireless communication function such as outputting an image on the display unit 2360 or outputting voice through a speaker, by dialing or communication with an external device 2370. Furthermore, when the electronic system 2300 includes a camera, the function unit 2340 may function as an image processor. In other example embodiments, when the electronic system 2300 is connected to a memory card for capacity expansion, the function unit 2340 may be a memory card controller. The function unit 2340 may transmit/receive a signal to/from the external device 2370 via a wired or wireless communication unit 2380. Moreover, when the electronic system 2300 requires a universal serial bus (USB) for function expansion, the functional unit 2340 may function as an interface controller. The semiconductor devices 10a to 10c according to various example embodiments may be included in at least one of the microprocessor unit 2320 and the function unit 2340.

FIG. 7C is a schematic block diagram of an electronic system 2400 having at least one of semiconductor devices 10a to 10c according to various example embodiments. Referring to FIG. 7C, an electronic system 2400 may include at least one of semiconductor devices 10a to 10c according to various example embodiments. The electronic system 2400 may be used in the fabrication of a mobile device or computer. For example, the electronic system 2400 may include a memory system 2412, a microprocessor 2414, a read only memory (RAM) 2416 and a user interface 2418 performing data communication using a bus 2420. The microprocessor 2414 may program or control the electronic system 2400. The RAM 2416 may be used as an operation memory of the microprocessor 2414. For example, the microprocessor 2414 or RAM 2416 may include at least one of the semiconductor devices 10a to 10c according to example embodiments. The microprocessor 2414, the RAM 2416 and/or the other components may be assembled in a single package. The user interface 2418 may be used in inputting data into the electronic system 2400, or outputting data from the electronic system 2400. A memory system 2412 may store codes for operating the microprocessor 2414, data processed by the microprocessor 2414, or externally input data. The microprocessor 2414 may include a controller and a memory.

FIG. 7D is a schematic view of a mobile apparatus 2500 including at least one of semiconductor devices 10a to 10c according to various example embodiments. The mobile apparatus 2500 may include a mobile phone or tablet PC. In addition, at least one of the semiconductor devices 10a to 10c according to various example embodiments may be used for a portable computer such as a notebook, a mpeg-1 audio layer 3 (MP3) player, a MP4 player, a navigation device, a solid state disk (SSD), a desktop computer, an automobile, and an electric appliance in addition to a mobile phone or tablet PC.

In a semiconductor device according to various example embodiments, various material patterns are sufficiently discharged to have a relatively small amount of accumulated charges, so that a profile of each material layer may be soft without being damaged.

In methods of fabricating a semiconductor device according to various example embodiments, charges accumulated in material layers can be sufficiently discharged, so that a profile of each material layer can be softly formed without being damaged.

The foregoing is illustrative of embodiments and is not to be construed as limiting thereof. Although a few embodiments have been described, those skilled in the art will readily appreciate that many modifications are possible in embodiments without materially departing from the novel teachings and advantages. Accordingly, all such modifications are intended to be included within the scope of the inventive concepts as defined in the claims. In the claims, means-plus-function clauses are intended to cover the structures described herein as performing the recited function, and not only structural equivalents but also equivalent structures. Therefore, it is to be understood that the foregoing is illustrative of various example embodiments and is not to be construed as limited to the specific embodiments disclosed, and that modifications to the disclosed embodiments, as well as other embodiments, are intended to be included within the scope of the appended claims.

What is claimed is:

1. A method of fabricating a semiconductor device, the method comprising:
forming a gate electrode structure on a substrate;
forming a first spacer material layer covering the gate electrode structure;
forming a second spacer material layer covering the first spacer material layer; and
etching the first and second spacer material layers using an etch-back process to fond first and second spacers.

2. The method of claim 1, wherein the etch-back process includes a plasma discharge process.

3. The method of claim 2, wherein the plasma discharge process includes one of nitrogen (N₂), an inert gas, and a mixture thereof.

4. The method of claim 2, wherein the etch-back process comprises:
continually performing a first etching process having a first etch selectivity and a second etching process having a second etch selectivity, the first etch selectivity being higher than the second etch selectivity.

5. The method of claim 4, wherein the etch-back process including periodically repeating the first etching process, the second etching process, and the plasma discharge process at least once.

6. The method of claim 4, wherein the first etching process includes a first gas containing carbon (C) and fluorine (F)

7. The method of claim 6, wherein the first etching process includes at least one of CF₄, C₂F₆, C₃F₆, and C₄F₈.

8. The method of claim 6, wherein the second etching process includes a second gas containing carbon (C), hydrogen (H) and fluorine (F).

9. The method of claim 8, wherein the second etching process includes CHF₃.

10. The method of claim 1, wherein the forming the first spacer material layer includes depositing silicon oxide using inner plasma.

11. The method of claim 1, wherein the forming the second spacer material layer includes depositing silicon nitride using remote plasma.

12. The method of claim 11, wherein the forming the second spacer material layer includes performing one of an atomic layer deposition (ALD) process and molecular layer deposition (MLD) process.

13. A method of fabricating a semiconductor device, the method comprising:
forming a gate electrode structure on a substrate;
forming a gate structure on the gate electrode structure including,
forming a spacer material layer covering the gate electrode structure, and
etching the spacer material layer using an etch-back process to form a spacer on a side of the gate electrode structure, the etch-back process including continually performing a first etching process using a gas containing a first fluorine (F) content, a second etching process using a gas containing a second F content lower than the first F content, and a plasma discharge process using a gas containing N₂;
implanting impurity ions into the substrate using the gate structure as an ion implantation mask to form source/drain regions;
forming an interlayer insulating layer covering the gate structure and the source/drain regions; and
forming a contact structure vertically penetrating the interlayer insulating layer to be in contact with one of the source/drain regions.

14. The method of claim 13, wherein the forming the gate electrode structure includes:
forming a gate insulating material layer on the substrate;
forming a gate electrode material layer on the gate insulating material layer;
forming a hard mask pattern on the gate electrode material layer; and
patterning the gate electrode material layer and the gate insulating material layer using the hard mask pattern to form a gate electrode and a gate insulating layer.

15. The method of claim 13, wherein the forming the contact structure includes:
forming a contact hole vertically penetrating the interlayer insulating layer to expose one of the source/drain regions;
forming a contact barrier metal layer on an inner wall of the contact hole; and
forming a metal plug on the contact barrier metal layer to fill the contact hole.

16. The method of claim 15, further comprising:
forming a capping layer on the interlayer insulating layer and the contact structure;
forming a via hole vertically penetrating the capping layer to expose a top surface of the contact structure;
forming a via barrier metal layer on the top surface of the contact structure and an inner wall of the via hole; and
forming a via plug on the via barrier metal layer to fill the via hole.

17. The method of claim 13, further comprising:
forming an epitaxial growth layer on the one of the source/drain regions; and
forming a silicide region in the epitaxial growth layer.

18. The method of claim 13, wherein the plasma discharge process includes exciting one of phosphorus (P), arsenic (As), boron (B), carbon (C), hydrogen (H), and nitrogen (N) into a plasma state to diffuse the one of phosphorus (P), arsenic (As), boron (B), carbon (C), hydrogen (H), and nitrogen (N) into the spacer material layer.

19. A method of fabricating a semiconductor device, the method comprising:
forming a gate electrode structure on a substrate;
forming at least one spacer material layer covering at least a portion of the gate electrode structure; and
etching the at least one spacer material layer using an etch-back process including continually performing a first etching process having a first etch selectivity, a second etching process having a second etch selectivity less than the first etch selectivity and a plasma ion implantation process.

20. The method of claim 19, wherein the plasma ion implantation process includes exciting one of phosphorus (P), arsenic (As), boron (B), carbon (C), hydrogen (H), and nitrogen (N) into a plasma state to diffuse the one of phosphorus (P), arsenic (As), boron (B), carbon (C), hydrogen (H), and nitrogen (N) into the at least one spacer material layer.
